(19) United States
(12) Patent Application Publication
(10) Pub. No.: US 2026/0136738 A1
(43) Pub. Date: May 14, 2026

(54) DISPLAY DEVICE

(71) Applicant: LG Display Co., Ltd., Seoul (KR)

(72) Inventor: Chanil PARK, Paju-si (KR)

(73) Assignee: LG Display Co., Ltd., Seoul (KR)

(21) Appl. No.: 19/320,939

(22) Filed: Sep. 5, 2025

(30) Foreign Application Priority Data
Nov. 14, 2024 (KR) 10-2024-0162198

(51) Int. Cl. H10H 29/49

(52) U.S. Cl. CPC H10H 29/49

(57) ABSTRACT

According to an aspect of the present disclosure, a display device includes a lower substrate having an active area and a non-active area adjacent to the active area. The active area includes a first area and a second area that surrounds the first area. A plurality of plate patterns is disposed on the lower substrate, and a plurality of line patterns is arranged between adjacent plate patterns of the plurality of plate patterns. A plurality of pixels is disposed on a plurality of plate patterns in the active area, among the plurality of plate patterns. The plurality of pixels are arranged in the first area and the second area with different pixel densities, such that the first area provides a higher resolution image while the second area provides stretchability. By combining distinct pixel densities with plate and line patterns, the display device ensures high resolution in the central viewing region and mechanical flexibility in the outer region, while maintaining overall display performance.

### CROSS-REFERENCE TO RELATED APPLICATIONS

This application claims the priority of Korean Patent Application No. 10-2024-0162198 filed on Nov. 14, 2024, in the Korean Intellectual Property Office, the disclosure of which is incorporated herein by reference.

### BACKGROUND

### Technical Field

The present disclosure relates to a display device, and more particularly to a stretchable display device which can be stretched.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Recently, a display device which is manufactured by forming a display unit and a wiring line on a flexible substrate such as plastic which is a flexible material so as to be stretchable in a specific direction and changed in various forms is getting attention as a next generation display device.

### BRIEF SUMMARY

The present disclosure relates to a stretchable display device that combines high image quality in the viewing center with mechanical flexibility at the periphery. This is achieved by dividing the active display area into two zones: a central first area with a high pixel density for enhanced resolution, and a surrounding second area with lower pixel density and interconnecting line patterns that allow stretchability. In this way, sharp image reproduction is provided where the user's eyes are focused, while the outer portions can deform without significant loss in display quality.

The structural configuration includes the use of plate patterns and dummy patterns. In the central region, plate patterns are arranged in direct contact to achieve maximum density, while in the outer region, plate patterns are arranged as separated islands and connected with line patterns that enable mechanical flexibility. Dummy patterns are positioned at boundary regions to enhance stability and increase durability during repeated stretching. Furthermore, brittle insulating layers such as buffer, interlayer, and passivation layers are formed only on rigid plate regions rather than in the spaces between plates. This reduces the likelihood of cracking during stretching and helps maintain protection of the circuit elements.

The electrical architecture is also arranged to ensure reliable operation. Gate, data, and power lines are routed only on plate and dummy patterns, while driver stages are distributed across opposite non active regions to balance electrical load and minimize voltage drop. With this arrangement, the display provides high resolution in the central area, mechanical stretchability and durability at the edges, and stable circuit performance under bending or extension. This structural combination allows both visual quality and mechanical reliability in a stretchable display device.

Various embodiments of the present disclosure provide a display device which improves a resolution in a center area in which an image is displayed.

Various embodiments of the present disclosure provide a display device which ensures stretchability of an outside area in which stretching is required.

Technical benefits of the present disclosure are not limited to the above-mentioned benefits, and other benefits, which are not mentioned above, can be clearly understood by those skilled in the art from the following descriptions.

In order to achieve the technical benefits as described above, according to an aspect of the present disclosure, a display device includes a lower substrate including an active area having a first area and a second area surrounding the first area, and a non-active area excluding the active area; a plurality of plate patterns on the lower substrate; a plurality of line patterns between the plurality of plate patterns on the lower substrate; and a plurality of pixels on a plurality of plate patterns in the active area, among the plurality of plate patterns, and the plurality of pixels is disposed in the first area and the second area with different pixel densities.

According to an aspect of the present disclosure, a display device includes a lower substrate including an active area having a first area and a second area surrounding the first area, and a non-active area excluding the active area; a plurality of plate patterns on the lower substrate; and a plurality of line patterns between the plurality of plate patterns on the lower substrate, and the plurality of plate patterns overlaps at least a part of the second area and does not overlap the first area.

According to an aspect of the present disclosure, a display device includes a lower substrate including an active area having a first area and a second area surrounding the first area, and a non-active area excluding the active area; a plurality of plate patterns on the lower substrate; a plurality of line patterns between the plurality of plate patterns on the lower substrate; and a plurality of pixels on a plurality of plate patterns in the active area, among the plurality of plate patterns. A plurality of plate patterns in the first area, among the plurality of plate patterns, is disposed to be in direct contact with an adjacent plate pattern and a plurality of plate patterns in the second area, among the plurality of plate patterns, is disposed to be spaced apart from each other.

Other detailed matters of the exemplary embodiments are included in the detailed description and the drawings.

In the case of the display device according to the exemplary embodiments of the present disclosure, in a first area which is a center area of an active area in which the stretching is not necessary and the user's eyes are focused, a high resolution image may be displayed. In a second area which is an outside area of the active area in which the stretching is necessary and the user's eyes are relatively less focused, the stretchability is ensured by a line pattern. Accordingly, in the case of the display device according to the exemplary embodiments of the present disclosure, in the outside area in which the stretching is necessary, the stretching is possible and in the center area in which the user's eyes are focused, a high resolution image can be displayed.

Further, in the case of the display device according to the exemplary embodiments of the present disclosure, as a part in which a resolution is switched, in a second area corresponding to a boundary part between the first area and the second area of the active area and/or a non-active area, a plurality of dummy patterns having a planar shape is disposed. Accordingly, the stretchability of the display device is ensured and a durability for the stretching is enhanced.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view schematically illustrating a display device according to exemplary embodiments of the present disclosure;

FIG. 2 is a plan view illustrating a display device according to exemplary embodiments of the present disclosure;

FIG. 3A is an enlarged plan view illustrating an example of a first area of a lower substrate included in a display device of FIG. 2;

FIG. 3B is an enlarged plan view illustrating another example of a first area of a lower substrate included in a display device of FIG. 2;

FIG. 3C is an enlarged plan view illustrating still another example of a first area of a lower substrate included in a display device of FIG. 2;

FIG. 4 is an enlarged plan view illustrating an example of a part EA of FIG. 2;

FIG. 5 is a cross-sectional view illustrating an example taken along the line III-III′ of FIG. 4;

FIG. 6 is a circuit diagram illustrating an example of a pixel included in a display device of FIG. 2;

FIGS. 7A to 7C are views for explaining an example of a driving method of a display device of FIG. 2;

FIG. 8 is a waveform chart for explaining an example of a driving method of a display device of FIG. 2;

FIG. 9 is a plan view illustrating a display device according to exemplary embodiments of the present disclosure; and

FIG. 10 is a plan view illustrating a display device according to exemplary embodiments of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When described as “connected” or “coupled,” unless the terms “directly” or “immediately” are used, the connection or coupling may include indirect connections or couplings through one or more other components positioned between the two elements.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

A display device according to exemplary embodiments of the present disclosure is a display device which is capable of displaying images even in a bent or extended state and is also referred to as a stretchable display device, a flexible display device and an extendable display device. As compared with the general display devices of the related art, the display device has not only a high flexibility, but also stretchability. Therefore, the user may bend or extend a display device and a shape of a display device may be freely changed in accordance with manipulation of a user. For example, when the user pulls the display device by holding ends of the display device, the display device may be extended to the pulling direction of the user. Alternatively, when the user disposes the display device on an outer surface which is not flat, the display device may be disposed to be bent in accordance with the shape of the outer surface of the wall. Further, when a force applied by the user is removed, the display device may return to its original shape.

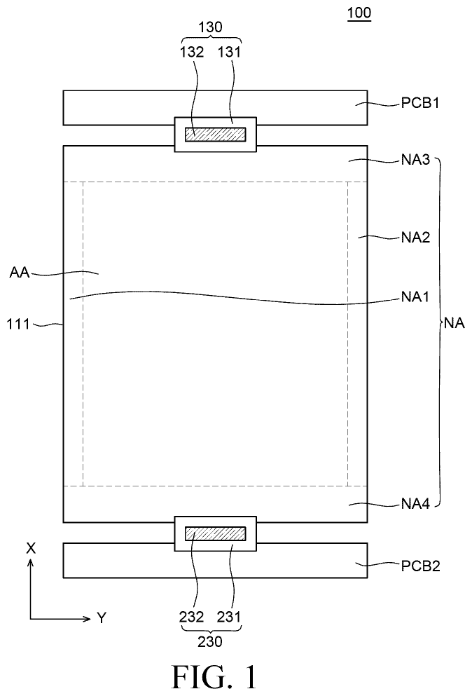

FIG. 1 is a plan view schematically illustrating a display device according to exemplary embodiments of the present disclosure.

In the meantime, for the convenience of description, among various configurations of the display device, only a lower substrate 111, a first flexible film 130, a second flexible film 230, a first printed circuit board PCB1, and a second printed circuit board PCB2 are illustrated.

Referring to FIG. 1, the lower substrate 111 supports several components of the display device 100. The lower substrate 111 may include an active area AA in which images are displayed and a non-active area NA excluding the active area AA. For example, the non-active area NA surrounds the active area AA.

On the active area AA, a plurality of pixels each including a display element and a circuit element is disposed and on the non-active area NA, a gate driver and a power supply for driving the plurality of pixels disposed in the active area AA are disposed.

In one exemplary embodiment, the non-active area NA includes a first non-active area NA1, a second non-active area NA2, a third non-active area NA3, and a fourth non-active area NA4.

The first non-active area NA1 and the second non-active area NA2 are disposed on both sides of the active area AA along a second direction Y. For example, the first non-active area NA1 is disposed in one side of the active area AA along the second direction Y and the second non-active area NA2 is disposed in the other side of the active area AA along the second direction Y, which is opposite to the first non-active area NA1. For example, the first non-active area NA1 is disposed in a left side of the active area AA and the second non-active area NA2 is disposed in a right side of the active area AA. A gate driver and a power supply are disposed on the first non-active area NA1 and the second non-active area NA2.

The third non-active area NA3 and the fourth non-active area NA4 are disposed on both sides of the active area AA along a first direction X. For example, the third non-active area NA3 is disposed in one side of the active area AA along the first direction X and the fourth non-active area NA4 is disposed in the other side of the active area AA along the first direction X, which is opposite to the third non-active area NA3. For example, the third non-active area NA3 is disposed on the top of the active area AA and the fourth non-active area NA4 is disposed on the bottom of the active area AA.

On the third non-active area NA3, a plurality of first pads connected to the first flexible film 130 and a plurality of link lines which transmits a signal to the active area AA from the plurality of first pads are disposed. The third non-active area NA3 may be an area between an upper portion of the active area AA and the plurality of first pads.

On the fourth non-active area NA4, a plurality of second pads connected to the second flexible film 230 and the plurality of link lines which transmits a signal to the active area AA from the plurality of second pads are disposed. The fourth non-active area NA4 may be an area between a lower portion of the active area AA and the plurality of second pads.

In one exemplary embodiment, the flexible films 130 and 230 and the printed circuit boards PCB1 and PCB2 are disposed on both sides of the display device 100. For example, the flexible films 130 and 230 include the first flexible film 130 and the second flexible film 230 disposed on both sides of the display device 100. The printed circuit boards PCB1 and PCB2 include a first printed circuit board PCB1 and a second printed circuit board PCB2 which are disposed on both sides of the display device 100 and are connected to the first flexible film 130 and the second flexible film 230, respectively.

The first flexible film 130 is a film in which various components are disposed on a first base film 131 having a flexibility and supplies signals to the plurality of pixels PX of the active area AA. The first flexible film 130 is bonded to the plurality of first pads disposed in the third non-active area NA3 and supplies various signals to the plurality of sub pixels of the active area AA through the first pad and the plurality of link lines. The first flexible film 130 includes a first base film 131 and a first driving IC 132. Further, various components may be disposed on the first flexible film 130.

Further, the second flexible film 230 is a film in which various components are disposed on a second base film 231 having a flexibility and supplies signals to the plurality of pixels PX of the active area AA. The second flexible film 230 is bonded to the plurality of second pads disposed in the fourth non-active area NA4 and supplies various signals to the plurality of pixels of the active area AA through the second pad and the plurality of link lines. The second flexible film 230 includes a second base film 231 and a second driving IC 232. Further, various components may be disposed on the second flexible film 230.

The first base film 131 and the second base film 231 supports a first driving IC 132 of the first flexible film 130 and a second driving IC 232 of the second flexible film 230, respectively. The first base film 131 and the second base film 231 may be formed of an insulating material, and for example, may be formed of an insulating material having a flexibility.

The first driving IC 132 and the second driving IC 232 process data for displaying images and a driving signal for processing the image. In FIG. 1, even though it is illustrated that the first driving IC 132 and the second driving IC 232 are mounted by the COF technique, it is not limited thereto and the first driving IC 132 and the second driving IC 232 may be mounted by a technique, such as a chip on glass (COG) or a tape carrier package (TCP).

The first printed circuit board PCB1 is connected to the first flexible film 130 and the second circuit board PCB2 is connected to the second flexible film 230. In each of the first printed circuit board PCB1 and the second printed circuit board PCB2, a controller, such as an IC chip or a circuit unit may be mounted. Further, in each of the first printed circuit board PCB1 and the second printed circuit board PCB2, a memory and a processor are also mounted. The first printed circuit board PCB1 and the second printed circuit board PCB2 may generate a signal for driving the pixel.

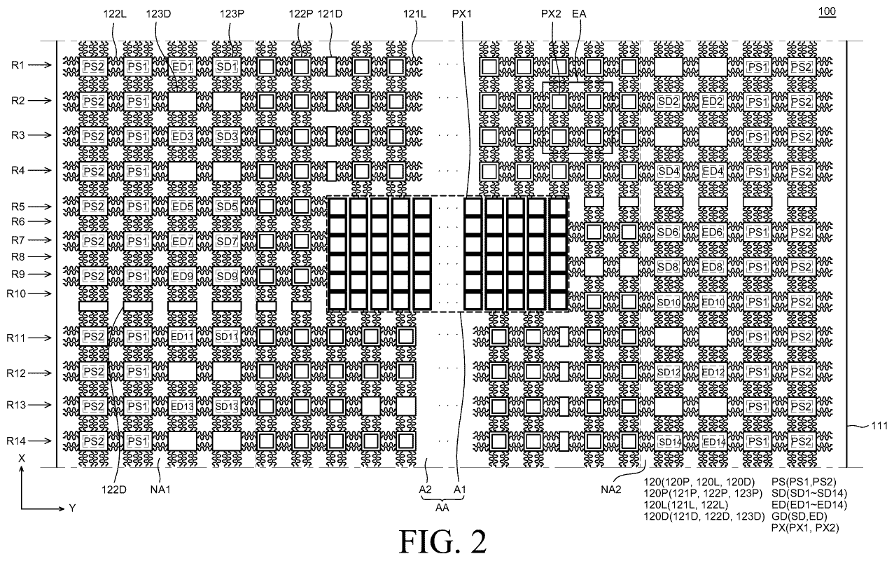

Hereinafter, the active area AA, the first non-active area NA1, and the second non-active area NA2 of the display device 100 will be described in more detail with reference to FIGS. 2 to 4.

FIG. 2 is a plan view illustrating a display device according to exemplary embodiments of the present disclosure.

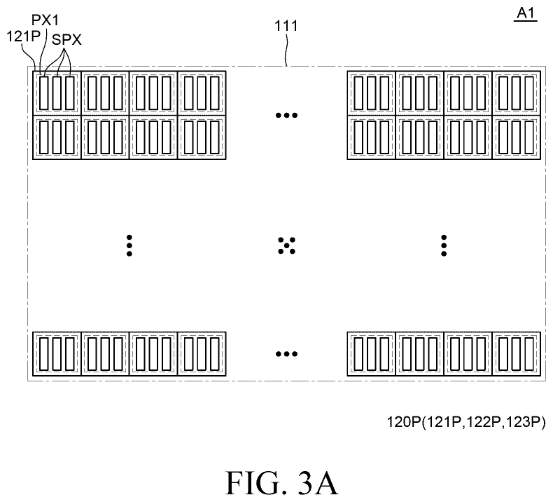

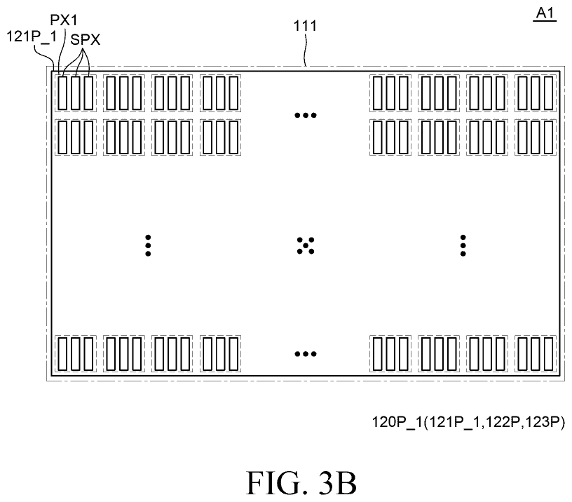

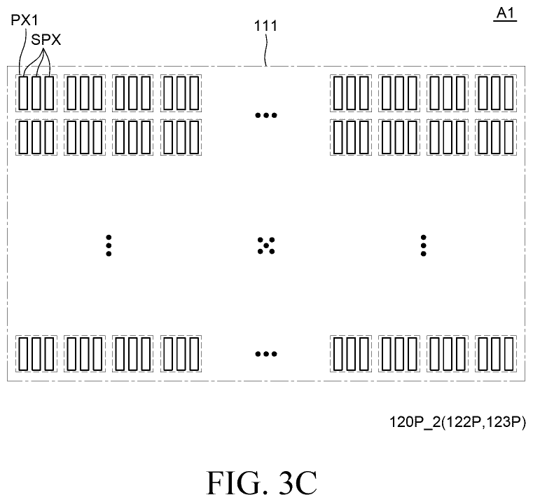

FIG. 3A is an enlarged plan view illustrating an example of a first area of a lower substrate included in a display device of FIG. 2.

FIG. 3B is an enlarged plan view illustrating another example of a first area of a lower substrate included in a display device of FIG. 2.

FIG. 3C is an enlarged plan view illustrating still another example of a first area of a lower substrate included in a display device of FIG. 2.

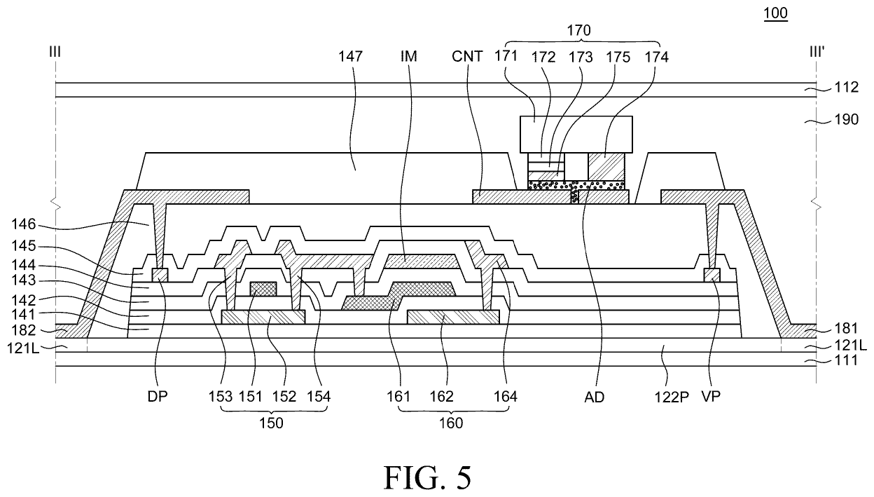

A display device 100 according to exemplary embodiments of the present disclosure includes a lower substrate 111, a pattern layer 120, a plurality of pixels PX, a gate driver GD, a data driver DD, and a power supply PS. In one exemplary embodiment, the display device 100 further includes an upper substrate (for example, an upper substrate 112 of FIG. 5).

The lower substrate 111 supports the pattern layer 120 on which the pixel PX, the gate driver GD, and the power supply PS are formed and the upper substrate 112 is disposed on the lower substrate 111 and covers various components of the display device 100. In one exemplary embodiment, the lower substrate 111 and the upper substrate 112 are flexible substrates and are configured by an insulating material which is bendable or stretchable.

Moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a timing when an object to be stretched is broken or cracked.

The pattern layer 120 may be disposed on the lower substrate 111. In the exemplary embodiment, the pattern layer 120 includes a plurality of plate patterns 120P disposed on the lower substrate 111, a plurality of line patterns 120L disposed between the plurality of plate patterns 120P on the lower substrate 111, and a plurality of dummy patterns 120D disposed on the lower substrate 111.

The plurality of plate patterns 120P includes a plurality of first plate patterns 121P and a plurality of second plate patterns 122P disposed in the active area AA and a plurality of third plate patterns 123P disposed in the non-active area NA. Further, the plurality of line patterns 120L includes a plurality of first line patterns 121L disposed in the active area AA and a plurality of second line patterns 122L disposed in the non-active area NA.

The active area AA includes a first area A1 in which the plurality of first plate patterns 121P is disposed and a second area A2 in which the plurality of second plate patterns 122P is disposed. The second area A2 may be an area of the active area AA excluding the first area A1. For example, the second area A2 surrounds the first area A1. For example, the first area A1 corresponds to the center area of the active area AA and the second area A2 corresponds to the outside area of the active area AA.

The plurality of plate patterns 120P will be described in more detail with reference to FIG. 3A. According to an exemplary embodiment, the plurality of plate patterns 120P disposed in the active area AA, for example, the plurality of first plate patterns 121P and the plurality of second plate patterns 122P disposed in the active area AA may have different densities in each area. For example, the plurality of first plate patterns 121P disposed in the first area A1 is disposed with a first density and the plurality of second plate patterns 122P disposed in the second area A2 is disposed with a second density which is lower than the first density.

In the meantime, in the present disclosure, a density (or a pattern density) with which the plate patterns are disposed is defined by a total area of a part in which the plate patterns are disposed with respect to an entire area of the corresponding area or defined by a total area of plate patterns included in a predetermined unit area. Here, an area in which each plate pattern is disposed is an area of an upper surface of each plate pattern.

To be more specific, the plurality of first plate patterns 121P may be disposed in the first area A1 with the first density. For example, the plurality of first plate patterns 121P may be disposed so as not to be spaced apart from each other on the first area A1. For example, as illustrated in FIGS. 2 and 3A, each of the plurality of first plate patterns 121P may be disposed to be in direct contact with an adjacent first plate pattern 121P.

Further, as illustrated in FIG. 2, the plurality of second plate patterns 122P may be disposed in the second area A2 with the second density. For example, the plurality of second plate patterns 122P is disposed in the form of islands which are spaced apart from each other.

In the meantime, in FIG. 3A, it has been described that the plurality of first plate patterns 121P is disposed in the first area A1, but the exemplary embodiment of the present disclosure is not limited thereto.

For example, referring to FIGS. 2 and 3B together, the plurality of plate patterns 120P_1 includes a first plate pattern 121P_1 disposed in the first area A1, a plurality of second plate patterns 122P disposed in the second area A2, and a plurality of third plate patterns 123P disposed in the non-active area NA.

In the exemplary embodiment, one first plate pattern 121P_1 is disposed on the first area A1. For example, the first plate pattern 121P_1 may have a size corresponding to a size of the first area A1, but is not limited thereto.

As another example, referring to FIGS. 2 and 3C together, the plurality of plate patterns 120P_2 includes a plurality of second plate patterns 122P disposed in the second area A2 and a plurality of third plate patterns 123P disposed in the non-active area NA. That is, on the first area A1, a separate plate pattern is not formed and/or disposed and in this case, a pixel PX is directly disposed on the lower substrate 111.

Referring to FIG. 2 again, the plurality of first line patterns 121L is disposed in the second area A2 of the active area AA, but is not disposed in the first area A1. For example, the plurality of first line patterns 121L connects second plate patterns 122P which are adjacent to each other in the second area A2 or connects a first plate pattern 121P which is disposed in the outermost side, among the plurality of first plate patterns 121P disposed in the first area A1, and the second plate pattern 122P. In contrast, as described with reference to FIG. 3A, in the first area A1, each of the plurality of first plate patterns 121P is disposed to be in direct contact with the adjacent first plate pattern 121P. Further, as described with reference to FIG. 3B, only one first plate pattern 121P_1 is disposed on the first area A1 and/or as described with reference to FIG. 3C, a separate plate pattern is not formed on the first area A1 so that a separate line pattern is not disposed in the first area A1.

The plurality of third plate patterns 123P disposed in the non-active area NA is disposed in the form of islands which are spaced apart from each other. For example, the plurality of third plate patterns 123P is disposed to be spaced apart from each other in the first non-active area NA1 and the second non-active area NA2. The plurality of second line patterns 122L connects third plate patterns 123P which are adjacent to each other, among the plurality of third plate patterns 123P disposed in the non-active area NA or connects a second plate pattern which is the most adjacent to the non-active area NA, among the plurality of second plate patterns 122P disposed in the second area A2 adjacent to the non-active area NA and a third plate pattern 123P adjacent thereto.

A plurality of pixels PX is formed on the plurality of first plate patterns 121P and the plurality of second plate patterns 122P disposed in the active area AA.

For example, referring to FIGS. 2 and 3A, the plurality of pixels includes a plurality of first pixels PX1 on the plurality of first plate patterns 121P in the first area A1 and a plurality of second pixels PX2 on the plurality of second plate patterns 122P in the second area A2.

In this case, as described above, the first density of the plurality of first plate patterns 121P disposed on the first area A1 is higher than the second density of the plurality of second plate patterns 122P disposed on the second area A2. Accordingly, a first pixel density of the pixel PX disposed in the first area A1 is higher than a second pixel density of the pixel PX disposed in the second area A2. That is, a resolution of the first area A1 corresponding to the center area of the active area AA is higher than a resolution of the second area A2 corresponding to the outside area.

In the meantime, in the present description, the pixel density may be defined as a total area of a part in which pixels are disposed, with respect to the entire area of the corresponding area or defined as a total area of pixels included in a predetermined unit area. Here, the area in which each pixel is disposed is defined as an area of an emission surface of each pixel.

Accordingly, in the case of the display device 100 according to the exemplary embodiments of the present disclosure, in a first area A1 which is a center area of an active area AA in which the stretching is not necessary and the user's eyes are focused, a high resolution image may be displayed. In a second area A2 which is an outside area of the active area AA in which the stretching is necessary and the user's eyes are relatively less focused, the stretchability is ensured by a line pattern. Accordingly, in the case of the display device 100 according to the exemplary embodiments of the present disclosure, in the outside area in which the stretching is necessary, the stretching is possible and in the center area in which the user's eyes are focused, a high resolution image can be displayed.

In the meantime, in the above description, it has been described that the plurality of first pixels PX1 is formed above each of the plurality of first plate patterns 121P disposed on the first area A1, but the exemplary embodiment of the present disclosure is not limited thereto.

For example, referring to FIGS. 2 and 3B, the plurality of first pixels PX1 is disposed on the first plate pattern 121P_1 on the first area A1 with the first pixel density. That is, one first plate pattern 121P_1 is disposed on the first area A1 so that the plurality of first pixels PX1 disposed on the first area A1 is disposed with the first pixel density which is higher than the second pixel density with which the second pixels PX2 are disposed on one first plate pattern 121P_1. Accordingly, in the first area A1 which is a center area of the active area AA in which the stretching is not necessary and the user's eyes are focused, a high resolution image may be displayed.

As another example, referring to FIGS. 2 and 3C, as described above, a separate plate pattern is not formed on the first area A1 so that the plurality of first pixels PX is directly formed on the lower substrate 111. For example, the plurality of first pixels PX1 disposed on the first area A1 is disposed with the first pixel density which is higher than the second pixel density with which the second pixels PX2 are disposed on the lower substrate 111. Accordingly, in the first area A1 which is a center area of the active area AA in which the stretching is not necessary and the user's eyes are focused, a high resolution image may be displayed.

Referring to FIG. 2 again, the gate driver GD and the power supply PS are formed on the plurality of third plate patterns 123P disposed on the non-active area NA, for example, on the first non-active area NA1 and the second non-active area NA2.

In the meantime, in FIGS. 2 and 3B, it has been illustrated that the plurality of first plate patterns 121P or 121P_1, the plurality of second plate patterns 122P, and the plurality of third plate patterns 123P are formed with a quadrangular shape, but are not limited thereto.

The plurality of first line patterns 121L and the plurality of second line patterns 122L have a wavy shape (for example, a sine wave shape), but are not limited thereto. For example, the plurality of first line patterns 121L and the plurality of second line patterns 122L may extend in a zigzag pattern or may be formed with various shapes such as a shape extended by connecting a plurality of rhombus-shaped substrates at vertexes or a shape in which semicircular or quadrant shaped substrates are connected to each other.

The gate driver GD supplies a gate signal to the plurality of pixels PX disposed in the active area AA. The gate driver GD includes a plurality of stages formed on the plurality of third plate patterns 123P and each stage of the gate driver GD may be electrically connected to each other by means of the plurality of gate connection lines. Accordingly, a gate signal output from any one of stages may be transmitted to the other stage. Each stage may sequentially supply the gate signal to the plurality of pixels PX connected to each stage.

In one exemplary embodiment, among the plurality of stages included in the gate driver GD, odd-numbered stages are disposed on the plurality of third plate patterns 123P disposed on the first non-active area NA1. Among the plurality of stages included in the gate driver GD, even-numbered stages are disposed on the plurality of third plate patterns 123P disposed on the second non-active area NA2.

For example, among the plurality of stages included in the gate driver GD, odd-numbered stages are disposed on a plurality of third plate patterns 123P disposed so as to correspond to odd-numbered pixel rows R1, R3, R5, . . . , R13 of the plurality of pixels PX, among the plurality of third plate patterns 123P disposed on the first non-active area NA1. Further, among the plurality of stages included in the gate driver GD, even-numbered stages are disposed on a plurality of third plate patterns 123P disposed so as to correspond to even-numbered pixel rows R2, R4, R6, . . . , R14 of the plurality of pixels PX, among the plurality of third plate patterns 123P disposed on the second non-active area NA2.

To be more specific, the gate driver GD includes a scan driver SD and an emission driver ED. The scan driver SD supplies a scan signal to the plurality of pixels PX disposed in the active area AA and includes a plurality of scan stages SD1 to SD14 and the emission driver ED supplies an emission signal to the plurality of pixels PX disposed in the active area AA and includes a plurality of emission stages ED1 to ED14.

The plurality of scan stages SD1 to SD14 included in the scan driver SD is disposed on the plurality of third plate patterns 123P to sequentially supply a scan signal to the plurality of pixels PX. For example, among the plurality of scan stages SD1 to SD14 included in the scan driver SD, odd-numbered scan stages SD1, SD3, SD5, . . . , SD13 are disposed on the plurality of third plate patterns 123P disposed on the first non-active area NA1. Among the plurality of scan stages SD1 to SD14 included in the scan driver SD, even-numbered scan stages SD2, SD4, SD6, . . . , SD14 are disposed on the plurality of third plate patterns 123P disposed on the second non-active area NA2. For example, the odd-numbered scan stages SD1, SD3, SD5, . . . , SD13 included in the scan driver SD are disposed on the plurality of third plate patterns 123P which are disposed on the first non-active area NA1 and disposed so as to correspond to odd-numbered pixel rows R1, R3, R5, . . . , R13. Further, the even-numbered scan stages SD2, SD4, SD6, . . . , SD14 included in the scan driver SD are disposed on the plurality of third plate patterns 123P which are disposed on the second non-active area NA2 and disposed so as to correspond to even-numbered pixel rows R2, R4, R6, . . . , R14. Accordingly, the odd-numbered scan stages SD1, SD3, SD5, . . . , SD13 disposed in the first non-active area NA1 and the even-numbered scan stages SD2, SD4, SD6, . . . , SD14 disposed in the second non-active area NA2 alternately output scan signals to sequentially supply the scan signals to the plurality of pixels disposed in each pixel row R1 to R14.

Further, the plurality of emission stages ED1 to ED14 included in the emission driver ED is disposed on the plurality of third plate patterns 123P to sequentially supply an emission signal to the plurality of pixels PX. For example, among the plurality of emission stages ED1 to ED14 included in the emission driver ED, odd-numbered emission stages ED1, ED3, ED5, . . . , ED13 are disposed on the plurality of third plate patterns 123P disposed on the first non-active area NA1. Among the plurality of emission stages ED1 to ED14 included in the emission driver ED, even-numbered emission stages ED2, ED4, ED6, . . . , ED14 are disposed on the plurality of third plate patterns 123P disposed on the second non-active area NA2. For example, the odd-numbered emission stages ED1, ED3, ED5, . . . , ED13 included in the emission driver ED are disposed on the plurality of third plate patterns 123P which are disposed on the first non-active area NA1 and disposed so as to correspond to odd-numbered pixel rows R1, R3, R5, . . . , R13. Further, the even-numbered emission stages ED2, ED4, ED6, . . . , ED14 included in the emission driver ED are disposed on the plurality of third plate patterns 123P which are disposed on the second non-active area NA2 and disposed so as to correspond to even-numbered pixel rows R2, R4, R6, . . . , R14. Accordingly, the odd-numbered emission stages ED1, ED3, ED5, . . . , ED13 disposed in the first non-active area NA1 and the even-numbered emission stages ED2, ED4, ED6, . . . , ED14 disposed in the second non-active area NA2 alternately output emission signals to sequentially supply the emission signals to the plurality of pixels disposed in each pixel row R1 to R14.

The power supply PS is electrically connected to the gate driver GD and the plurality of pixels PX to supply a driving voltage. Further, the power supply PS is connected to the plurality of pixels PX to supply a pixel driving voltage to each of the plurality of pixels PX.

For example, the power supply PS includes a first power supply PS1 and a second power supply PS2. The first power supply PS1 is disposed on the plurality of third plate patterns 123P disposed on the first non-active area NA1 and the second non-active area NA2 and supplies a high potential power voltage to the plurality of pixels PX. The second power supply PS2 is disposed on the plurality of third plate patterns 123P disposed on the first non-active area NA1 and the second non-active area NA2 and supplies a low potential power voltage to the plurality of pixels PX.

As described above, only odd-numbered stages of the gate driver GD are disposed on the plurality of third plate patterns 123P disposed on the first non-active area NA1 and only even-numbered stages of the gate driver GD are disposed on the plurality of third plate patterns 123P disposed on the second non-active area NA2. Accordingly, the stages of the gate driver GD are not disposed on the plurality of third plate patterns 123P disposed so as to correspond to the even-numbered pixel rows R2, R4, R6, . . . , R14, among the plurality of third plate patterns 123P disposed on the first non-active area NA1. The stages of the gate driver GD are not disposed on the plurality of third plate patterns 123P disposed so as to correspond to the odd-numbered pixel rows R1, R3, R5, . . . , R13, among the plurality of third plate patterns 123P disposed on the second non-active area NA2.

In contrast, each of the first power supply PS1 and the second power supply PS2 is disposed on the plurality of third plate patterns 123P disposed so as to correspond to all the pixel rows R1 to R14. That is, a pixel driving voltage (for example, a high potential power voltage supplied by the first power supply PS1 and a low potential power voltage supplied by the second power supply PS2) is supplied to the plurality of pixels PX of all the pixel rows R1 to R14 disposed in the active area AA in both non-active areas of the non-active area NA, that is, in the first non-active area NA1 and the second non-active area NA2. Accordingly, degradation of an image quality due to the voltage drop (IR drop) may be suppressed.

The plurality of dummy patterns 120D includes a plurality of first dummy patterns 121D disposed in the active area AA and a plurality of second dummy patterns 122D and a plurality of third dummy patterns 123D disposed in the non-active area NA. In the present disclosure, the plurality of dummy patterns 120D corresponds to a pattern having a planar shape, similar to the plurality of plate patterns 120P as described above, but a circuit element for configuring the pixel PX, the gate driver GD, or the power supply PS is not disposed on the plate-shaped pattern. That is, on the plurality of dummy patterns 120D, only a connection line disposed on the line pattern 120L extends to an upper portion of the corresponding dummy pattern 120D.

The plurality of first dummy patterns 121D is disposed on the second area A2. For example, the plurality of first dummy patterns 121D is disposed on a virtual extending line for any one side, among a plurality of sides of the first area A1 and is (e.g., sequentially) spaced apart from each other along a direction parallel to the any one side.

Specifically, as illustrated in FIG. 2, the plurality of first dummy patterns 121D is (e.g., sequentially) spaced apart from each other along a first direction X parallel to a first side, on a virtual extending line of the second area A2 for the first side (for example, a left side) of the first area A1, for example, on the virtual extending line extending from the first side in the first direction X, the plurality of first dummy patterns 121D is (e.g., sequentially) spaced apart from each other along the first direction X parallel to a second side, on a virtual extending line of the second area A2 for the second side (for example, a right side) which is opposite to the first side of the first area A1, for example, on the virtual extending line extending from the second side in the first direction X, the plurality of first dummy patterns 121D is (e.g., sequentially) spaced apart from each other along the second direction Y parallel to a third side, on a virtual extending line of the second area A2 for the third side (for example, a upper side) of the first area A1, for example, on the virtual extending line extending from the third side in the second direction Y, and/or the plurality of first dummy patterns 121D is (e.g., sequentially) spaced apart from each other along the second direction Y parallel to a fourth side, on a virtual extending line of the second area A2 for the fourth side (for example, a lower side) which is opposite to the third side of the first area A1, for example, on the virtual extending line extending from the fourth side in the second direction Y.

The plurality of first dummy patterns 121D is connected to the adjacent second plate pattern 122P by the plurality of first line patterns 121L disposed in the active area AA, for example, in the second area A2.

As described above, in the case of the display device 100 according to the exemplary embodiments of the present disclosure, in the second area A2 corresponding to a part in which the resolution is switched, for example, a boundary part between the first area A1 and the second area A2, the plurality of first dummy patterns 121D having a planar shape is disposed. Therefore, the stretchability of the display device 100 is ensured and the durability for the stretching is enhanced.

Further, the plurality of second dummy patterns 122D disposed on the non-active area NA, for example, on the first non-active area NA1 and the second non-active area NA2 is (e.g., sequentially) disposed to be spaced apart from each other along a direction parallel to an extending direction of a virtual extending line, on the active area AA, for example, the virtual extending line in which the plurality of first dummy patterns 121D disposed in the second area A2 is disposed.

Specifically, as illustrated in FIG. 2, the plurality of second dummy patterns 122D is (e.g., sequentially)spaced apart from each other along a first direction X parallel to a first side, on a virtual extending line of the first non-active area NA1 for the first side (for example, a left side) of the first area A1, for example, on the virtual extending line extending from the first side in the first direction X. The plurality of second dummy patterns 122D is (e.g., sequentially) spaced apart from each other along the first direction X parallel to a second side, on a virtual extending line of the second non-active area NA2 for the second side (for example, a right side) which is opposite to the first side of the first area A1, for example, on the virtual extending line extending from the second side in the first direction X.

The plurality of second dummy patterns 122D may be connected to an adjacent third plate pattern 123P by the plurality of second line patterns 122L disposed in the non-active area NA, for example, in the first non-active area NA1 and the second non-active area NA2.

As described above, in the case of the display device 100 according to the exemplary embodiments of the present disclosure, not only in the active area AA, but also in the non-active area NA, in a part corresponding to a boundary part between the active area AA and the non-active areas NA1 and NA2, the plurality of second dummy patterns 122D having a planar shape is disposed. Therefore, the stretchability of the display device 100 is further ensured and the durability for the stretching is further enhanced.

In the meantime, as described above, the stages of the gate driver GD are not disposed on the plurality of third plate patterns 123P disposed so as to correspond to the even-numbered pixel rows R2, R4, R6, . . . , R14, among the plurality of third plate patterns 123P disposed on the first non-active area NA1. The stages of the gate driver GD are not disposed on the plurality of third plate patterns 123P disposed so as to correspond to the odd-numbered pixel rows R1, R3, R5, . . . , R13, among the plurality of third plate patterns 123P disposed on the second non-active area NA2. According to the exemplary embodiment, a plurality of third plate patterns 123P in which the stages of the gate driver GD are not disposed, among the plurality of third plate patterns 123P disposed on the non-active area NA, is defined as a plurality of third dummy patterns 123D.

In the meantime, even though in FIG. 2, it is illustrated that the plurality of first dummy patterns 121D, the plurality of second dummy patterns 122D, and the plurality of third dummy patterns 123D have a quadrangular shape, it is not limited thereto.

In one exemplary embodiment, the plurality of plate patterns 120P, the plurality of line patterns 120L, and the plurality of dummy patterns 120D of the pattern layer 120 may be more rigid than the lower substrate 111 and the upper substrate 112. Accordingly, moduli of elasticity and hardnesses of the plurality of plate patterns 120P, the plurality of line patterns 120L, and the plurality of dummy patterns 120D may be higher than the modulus of elasticity and the hardness of the lower substrate 111. For example, moduli of elasticity of the plurality of plate patterns 120P, the plurality of line patterns 120L, and the plurality of dummy patterns 120D may be 1000 times higher than the modulus of elasticity of the lower substrate 111 and the upper substrate 112, but the exemplary embodiment of the present disclosure is not limited thereto.

The plurality of plate patterns 120P, the plurality of line patterns 120L, and the plurality of dummy patterns 120D may be formed of a plastic material having a flexibility lower than those of the lower substrate 111 and the upper substrate 112.

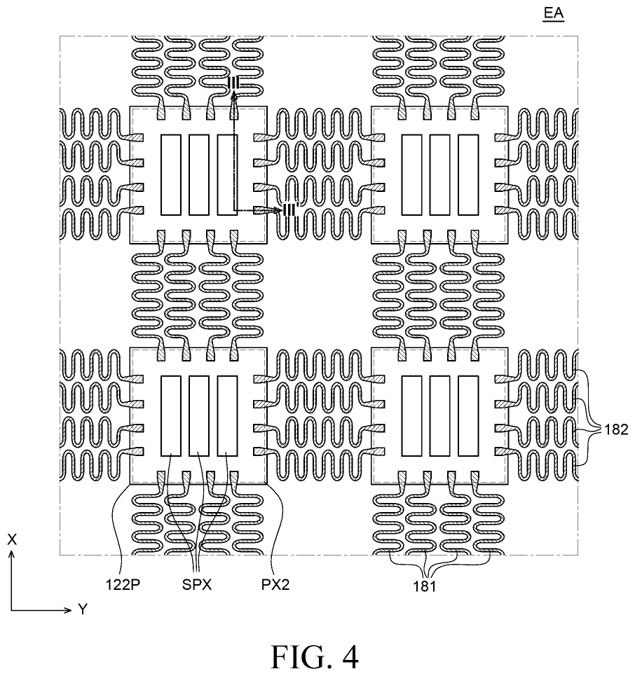

FIG. 4 is an enlarged plan view illustrating an example of a part EA of FIG. 2.

FIG. 5 is a cross-sectional view illustrating an example taken along the line III-III′ of FIG. 4.

Referring to FIGS. 1 to 4, a plurality of first plate patterns 120P, 120P_1, 120P_2 is disposed on the active area AA of the lower substrate 111. For example, as described with reference to FIG. 3A, the plurality of first plate patterns 121P is disposed on the first area A1 corresponding to a center area of the active area AA. As described with reference to FIG. 3B, one first plate pattern 121P_1 is disposed on the first area A1 or as described with reference to FIG. 3C, a separate plate pattern is not formed on the first area A1.

Further, the plurality of second plate patterns 122P may be disposed on the second area A2 corresponding to the outside area of the active area AA. The plurality of second plate patterns 122P is spaced apart from each other to be disposed on the lower substrate 111. For example, the plurality of second plate patterns 122P may be disposed on the lower substrate 111 in a matrix, but is not limited thereto.

A pixel including a plurality of sub pixels SPX is disposed on the first area A1 and the second area A2 of the active area AA. For example, a plurality of first pixels PX1 including a plurality of sub pixels SPX is disposed on the first area A1 with a first pixel density and a plurality of second pixels PX2 including a plurality of sub pixels SPX is disposed on the second area A2 with a second pixel density.

For example, as described with reference to FIG. 3A, when the plurality of first plate patterns 121P is disposed in the first area A1 with a first density (first pattern density), the plurality of first pixels PX1 is disposed on each of the plurality of first plate patterns 121P with the first pixel density. Here, the first density (first pattern density) with which the plurality of first plate patterns 121P is disposed has substantially the same value as the first pixel density, but is not limited thereto.

As another example, as described with reference to FIG. 3B, when one first plate pattern 121P_1 is disposed in the first area A1, the plurality of first pixels PX1 is disposed on one first plate pattern 121P_1 with the first pixel density.

As still another example, as described with reference to FIG. 3C, when a separate plate pattern is not formed in the first area A1, the plurality of first pixels PX1 is directly formed on the lower substrate 111 and is disposed with the first pixel density.

Further, as described with reference to FIG. 2, when the plurality of second plate patterns 122P is disposed in the second area A2 with a second density (second pattern density), the plurality of second pixels PX2 is disposed on each of the plurality of second plate patterns 122P with the second pixel density. Here, the second density (second pattern density) with which the plurality of second plate patterns 122P is disposed has substantially the same value as the second pixel density, but is not limited thereto.

Each of the plurality of sub pixels SPX may include an LED 170 (or a light emitting element) which is a display element and a circuit element for driving the LED 170, for example, at least one transistor. However, this is just illustrative and in the sub pixel SPX, the display element is not limited to an LED, and may also be changed to an organic light emitting diode.

The plurality of sub pixels SPX may include a red sub pixel, a green sub pixel, and a blue sub pixel, but is not limited thereto and colors of the plurality of sub pixels SPX may be deformed to various colors as needed.

The plurality of sub pixels SPX may be connected to a plurality of connection lines 181 and 182. For example, the plurality of sub pixels SPX may be electrically connected to a first connection line 181 extending in the first direction X and a second connection line 182 extending in the second direction Y.

Hereinafter, a cross-sectional structure of the display device 100 according to an exemplary embodiment of the present disclosure in the active area AA will be described in more detail with further reference to FIG. 5.

Referring to FIG. 5, on the active area AA of the lower substrate 111, for example, on the second area A2, a plurality of second plate patterns 122P and a plurality of first line patterns 121L which connects adjacent second plate patterns 122P are disposed.

A plurality of inorganic insulating layers may be disposed on the plurality of second plate patterns 122P. For example, a plurality of inorganic insulating layers may include a buffer layer 141, a gate insulating layer 142, a first interlayer insulating layer 143, a second interlayer insulating layer 144, and a passivation layer 145. However, in addition to the above-described inorganic insulating layers, another inorganic insulating layer may be additionally disposed or one or more of the above-described inorganic insulating layers may be omitted and a configuration of the plurality of inorganic insulating layers is not limited thereto.

The buffer layer 141 is disposed on the plurality of second plate patterns 122P. The buffer layer 141 includes an insulating material and is formed on the plurality of second plate patterns 122P to protect various components of the display device 100 from permeation of moisture and oxygen from the outside of the lower substrate 111 and the plurality of second plate patterns 122P. According to the exemplary embodiment, the buffer layer 141 may be omitted depending on a structure or a characteristic of the display device 100.

In one exemplary embodiment, the buffer layer 141 may be formed only in an area which overlaps the plurality of first plate patterns 121P, the plurality of second plate patterns 122P, and the plurality of third plate patterns 123P. As described above, the buffer layer 141 may be formed of an inorganic material so that the buffer layer 141 may be easily cracked or damaged during a process of stretching the display device 100. Therefore, the buffer layer 141 is not formed in an area between the plurality of first plate patterns 121P, the plurality of second plate patterns 122P, and the plurality of third plate patterns 123P. However, the buffer layer 141 is patterned in the shape of the plurality of first plate patterns 121P, the plurality of second plate patterns 122P, and the plurality of third plate patterns 123P to be formed only on the plurality of first plate patterns 121P, the plurality of second plate patterns 122P, and the plurality of third plate patterns 123P. Therefore, in case of the display device 100 according to the exemplary embodiment of the present disclosure, the buffer layer 141 is formed only in an area overlapping the plurality of first plate patterns 121P, the plurality of second plate patterns 122P, and the plurality of third plate patterns 123P which are rigid patterns. Therefore, even though the display device 100 is bent or extended to be deformed, the damage of various components of the display device 100 may be suppressed.

A switching transistor 150 and a driving transistor 160 are disposed on the buffer layer 141.

First, a switching active layer 152 of the switching transistor 150 and a driving active layer 162 of the driving transistor 160 are disposed on the buffer layer 141. For example, the switching active layer 152 of the switching transistor 150 and the driving active layer 162 of the driving transistor 160 may be formed of oxide semiconductor, but are not limited thereto and may be formed of amorphous silicon (a-Si), polycrystalline silicon (poly-Si), or an organic semiconductor.

The gate insulating layer 142 is disposed on the switching active layer 152 of the switching transistor 150 and the driving active layer 162 of the driving transistor 160. The gate insulating layer 142 includes an insulating material and electrically insulates the switching gate electrode 151 from the switching active layer 152 of the switching transistor 150 and electrically insulates the driving gate electrode 161 from the driving active layer 162 of the driving transistor 160.

The switching gate electrode 151 of the switching transistor 150 and the driving gate electrode 161 of the driving transistor 160 are disposed on the gate insulating layer 142. The switching gate electrode 151 and the driving gate electrode 161 are disposed on the gate insulating layer 142 to be spaced apart from each other. The switching gate electrode 151 overlaps the switching active layer 152 and the driving gate electrode 161 overlaps the driving active layer 162. The switching gate electrode 151 and the driving gate electrode 161 include various metal materials.

The first interlayer insulating layer 143 is disposed on the switching gate electrode 151 and the driving gate electrode 161. The first interlayer insulating layer 143 includes an insulating material and insulates the driving gate electrode 161 of the driving transistor 160 from an intermediate metal layer IM.

An intermediate metal layer IM is disposed on the first interlayer insulating layer 143. The intermediate metal layer IM includes various metal material and overlaps the driving gate electrode of the driving transistor 160 to form a storage capacitor.

The second interlayer insulating layer 144 is disposed on the intermediate metal layer IM. The second interlayer insulating layer 144 includes an insulating material and insulates the switching gate electrode 151 from the switching source electrode 153 and the switching drain electrode 154 of the switching transistor 150. The second interlayer insulating layer 144 insulates the intermediate metal layer IM from the driving source electrode and the driving drain electrode 164 of the driving transistor 160.

The switching source electrode 153 and the switching drain electrode 154 of the switching transistor 150 and the driving source electrode and the driving drain electrode 164 of the driving transistor 160 are disposed on the second interlayer insulating layer 144. The switching source electrode 153 and the switching drain electrode 154 of the switching transistor 150 are disposed on the same layer to be spaced apart from each other and the driving source electrode and the driving drain electrode 164 of the driving transistor 160 are disposed on the same layer to be spaced apart from each other. The switching source electrode 153 and the switching drain electrode 154 are electrically connected to the switching active layer 152 through a contact hole which passes through the gate insulating layer 142, the first interlayer insulating layer 143, and the second interlayer insulating layer 144. The driving source electrode and the driving drain electrode 164 are electrically connected to the driving active layer 162 through a contact hole which passes through the gate insulating layer 142, the first interlayer insulating layer 143, and the second interlayer insulating layer 144. The switching drain electrode 154 of the switching transistor 150 is electrically connected to the driving gate layer 161 of the driving transistor 160 through a contact hole which passes through the first interlayer insulating layer 143 and the second interlayer insulating layer 144.

The switching source electrode 153, the switching drain electrode 154, the driving source electrode, and the driving drain electrode 164 may include various metal materials.

Further, a gate pad, a data pad DP, and a voltage pad VP may be disposed on the second interlayer insulating layer 144.

The gate pad is connected to the first connection line 181 through a contact hole to transmit a gate signal to the plurality of sub pixels SPX. For example, the gate signal supplied from the first connection line 181 may be transmitted to the switching gate electrode 151 of the switching transistor 150 from the gate pad through a wiring line formed on the second plate pattern 122P.

The data pad DP is connected to the second connection line 182 through a contact hole to transmit a data signal to the plurality of sub pixels SPX. For example, the data signal supplied from the second connection line 182 may be transmitted to the switching source electrode 153 of the switching transistor 150 from the data pad DP through a wiring line formed on the second plate pattern 122P.

The voltage pad VP is connected to the first connection line 181 through a contact hole to transmit a power voltage to the plurality of sub pixels SPX. For example, the power voltage supplied from the first connection line 181 may be transmitted to the n-electrode 174 of the LED 170 from the voltage pad VP through a connection pattern CNT formed on the second plate pattern 122P.

The gate pad, the data pad DP, and the voltage pad VP may include various metal materials, for example, the same material as the switching source electrode 153, the switching drain electrode 154, and the driving drain electrode 164.

The passivation layer 145 may be disposed on the switching transistor 150, the driving transistor 160, the gate pad, the data pad DP, and the voltage pad VP. The passivation layer 145 includes an insulating material and protects various components disposed below the passivation layer 145 from moisture and oxygen.

In the meantime, the gate insulating layer 142, the first interlayer insulating layer 143, the second interlayer insulating layer 144, and the passivation layer 145 are patterned to be the same as the buffer layer 141 to be formed only in an area overlapping the plurality of first plate patterns 121P, the plurality of second plate patterns 122P, and the plurality of third plate patterns 123P. The gate insulating layer 142, the first interlayer insulating layer 143, the second interlayer insulting layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 may also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of first plate patterns 121P, the plurality of second plate patterns 122P, and the plurality of third plate patterns 123P. However, the gate insulating layer 142, the first interlayer insulating layer 143, the second interlayer insulating layer 144, and the passivation layer 145 are patterned to have a shape of the plurality of plurality of first plate patterns 121P, the plurality of second plate patterns 122P, and the plurality of third plate patterns 123P to be formed only on the plurality of first plate patterns 121P, the plurality of second plate patterns 122P, and the plurality of third plate patterns 123P.

The planarization layer 146 may be disposed on the passivation layer 145. The planarization layer 146 planarizes upper portions of the switching transistor 150 and the driving transistor 160. The planarization layer 146 may be configured by a single layer or a plurality of layers and may be formed of an organic material.

In the exemplary embodiment, the planarization layer 146 may be disposed so as to cover top surfaces and side surfaces of the buffer layer 141, the gate insulating layer 142, the first interlayer insulating layer 143, the second interlayer insulating layer 144, and the passivation layer 145 on the plurality of second plate patterns 122P. The planarization layer 146 surrounds the buffer layer 141, the gate insulating layer 142, the first interlayer insulating layer 143, the second interlayer insulating layer 144, and the passivation layer 145 together with the plurality of second plate patterns 122P. For example, the planarization layer 146 may be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of second plate patterns 122P.

Referring to FIGS. 2 to 5, the plurality of connection lines 181 and 182 may be disposed on the plurality of first line patterns 121L and the plurality of second line patterns 122L. The plurality of connection lines 181 and 182 electrically connects the pads on the plurality of first plate patterns 121P, pads on the plurality of second plate patterns 122P, and pads on the plurality of third plate patterns 123P. The plurality of connection lines 181 and 182 may extend onto the plurality of second plate patterns 122P so as to be electrically connected to the pad on the plurality of second plate patterns 122P. The plurality of first line patterns 121L is not disposed in an area where the plurality of connection lines 181 and 182 is not disposed, among areas between the plurality of second plate patterns 122P. Further, even though it is not illustrated in the drawing, the plurality of connection lines 181 and 182 is disposed on the plurality of second line patterns 122L to be electrically connected to the pads on the plurality of first plate patterns 121P, the pads on the plurality of second plate patterns 122P, and the pads on the plurality of third plate patterns 123P.

The plurality of connection lines 181 and 182 may include a plurality of first connection lines 181 and a plurality of second connection lines 182. The first connection line 181 and the second connection line 182 are disposed between the plurality of first plate patterns 121P, the plurality of second plate patterns 122P, and the plurality of third plate patterns 123P. For example, the first connection line 181 is a wiring line extending in the first direction X, between the plurality of first plate patterns 121P and the plurality of second plate patterns 122P, between the plurality of second plate patterns 122P, between the plurality of first plate patterns 121P and the plurality of third plate patterns 123P, and between the plurality of second plate patterns 122P and the plurality of third plate patterns 123P. The second connection line 182 is a wiring line extending in the second direction Y, between the plurality of first plate patterns 121P and the plurality of second plate patterns 122P, between the plurality of second plate patterns 122P, between the plurality of first plate patterns 121P and the plurality of third plate patterns 123P, and between the plurality of second plate patterns 122P and the plurality of third plate patterns 123P. The plurality of connection lines 181 and 182 may include a conductive material.

In the case of a general display device, various wiring lines, such as a plurality of gate lines and a plurality of data lines, extend between the plurality of sub pixels with a linear shape and the plurality of sub pixels is connected to one signal line. Therefore, in the general display device, various wiring lines, such as a gate line, a data line, a high potential voltage line, and a reference voltage line, extend from one side to the other side of the display device without being disconnected on the substrate.

In contrast, in the display device 100 according to the exemplary embodiment of the present disclosure, various wiring lines, such as a gate line, a data line, a high potential voltage line, a reference voltage line, or an initialization voltage line having a straight line shape which are considered to be used for the general display device, are disposed only on the plurality of plate patterns 120P and the plurality of dummy patterns 120D. That is, in the display device 100 according to the exemplary embodiment of the present disclosure, a straight wiring line is disposed only on the plurality of plate patterns 120P and the plurality of dummy patterns 120D.

In the display device 100 according to the exemplary embodiment of the present disclosure, the pads on the two adjacent second plate patterns 122P may be connected by the first connection lines 181. For example, the plurality of first connection lines 181 electrically connects gate pads, data pads DP, or voltage pads VP on two adjacent second plate patterns 122P. Accordingly, the display device 100 according to the exemplary embodiment of the present disclosure may include a plurality of first connection lines 181 which electrically connects various wiring lines, such as a gate line, a data line, a high potential voltage line, and a reference voltage line, between the plurality of second plate patterns 122P.

For example, the gate line extending in the first direction X may be disposed on the plurality of second plate patterns 122P and the gate pad may be disposed on both ends of the gate line. At this time, the plurality of gate pads on the plurality of second plate patterns 122P adjacent to each other in the first direction X may be connected to each other by the first connection line 181 which serves as a gate line. Therefore, the gate line disposed on the plurality of second plate patterns 122P and the first connection line 181 disposed on the first line pattern 121L may serve as one gate line. Further, wiring lines which extend in the first direction X, among all various wiring lines which may be included in the display device 100, such as an emission signal line, a low potential voltage line, and a high potential voltage line, may also be electrically connected by the first connection line 181, as described above.

As another example, a data line extending in the second direction Y may be disposed on the plurality of second plate patterns 122P and the data pad DP may be disposed on both ends of the data line. In this case, the data pad DP on the plurality of second plate patterns 122P adjacent to each other in the second direction Y may be connected to each other by the second connection line 182 which serves as a data line. Therefore, the data line disposed on the plurality of second plate patterns 122P and the second connection line 182 disposed on the first line pattern 121L may serve as one data line. Further, wiring lines which extend in the second direction Y, among all various wiring lines which may be included in the display device 100, such as a data line, a high potential voltage line, a low potential voltage line, or a reference voltage line may also be electrically connected by the second connection line 182, as described above.

Referring to FIG. 5, the plurality of first connection lines 181 is disposed to be in contact with a top surface and a side surface of the planarization layer 146 disposed on the second plate pattern 122P. The first connection line 181 is disposed on the top surface of the first line pattern 121L and both ends thereof extend onto the second plate pattern 122P to be formed.

However, there is no need to place a rigid pattern in an area where the first connection line 181 and the second connection line 182 are not disposed so that the plurality of first line patterns 121L and the plurality of second line patterns 122L are not disposed.

The connection pattern CNT is disposed on the planarization layer 146. The connection pattern CNT electrically connects the LED 170 and the driving transistor 160 and the low potential power line. For example, the connection pattern CNT may electrically connect the drain electrode of the driving transistor 160 and the p-electrode 175 of the LED 170 and may electrically connect the low potential power line and the n-electrode 174 of the LED 170. In this case, the connection pattern CNT extends from the connection lines 181 and 182 which transmit the low potential power voltage to be integrally formed with the connection lines 181 and 182. Therefore, when the display device 100 is driven, different voltage levels applied to the connection pattern CNT are transmitted to the n-electrode 174 and the p-electrode 175 so that the LED 170 emits light.

A bank 147 is formed on the connection pattern CNT, the connection lines 181 and 182, and the planarization layer 146. The bank 147 includes an insulating material and divides adjacent sub pixels SPX. The bank 147 is disposed so as to cover at least a part of the connection pattern CNT, the connection lines 181 and 182, and the planarization layer 146.

The LED 170 is disposed on the connection pattern CNT. The LED 170 may include an n-type layer 171, an active layer 172, a p-type layer 173, an n-electrode 174, and a p-electrode 175.

A p-type layer 173 doped with a p-type impurity is disposed on the connection pattern CNT, an n-type layer 171 doped with an n-type impurity is disposed on the p-type layer 173, and an active layer 172 (or an emission layer) is disposed between the n-type layer 171 and the p-type layer 173.

Further, after sequentially laminating the n-type layer 171, the active layer 172, and the p-type layer 173, a predetermined part is etched to expose a part of the n-type layer 171. Thereafter, the n-electrode 174 is disposed on one surface of the n-type layer 171 exposed in the etched area and the p-electrode 175 is disposed on one surface of the p-type layer 173 disposed in a non-etched area to form the LED 170.

An adhesive layer AD is disposed between the LED 170 and the connection pattern CNT. For example, the adhesive layer AD may be disposed between the n-electrode 174 and the p-electrode 175 of the LED 170 and the connection pattern CNT. For example, the adhesive layer AD is a conductive adhesive layer and the n-electrode 174 and the p-electrode 175 are electrically connected to the connection pattern CNT by means of the adhesive layer AD.

The upper substrate 112 is disposed on the LED 170 and the lower substrate 111. The upper substrate 112 supports various components disposed below the upper substrate 112.

Even though not illustrated in FIG. 5, a polarization layer may be disposed on the upper substrate 112. The polarization layer may function to polarize light incident from the outside of the display device 100 to reduce the external light reflection. Further, an optical film other than the polarization layer may be disposed on the upper substrate 112.

A filling layer 190 may be disposed between the lower substrate 111 and the upper substrate 112. The filling layer 190 may be fully filled in an empty space between the lower substrate 111 and the upper substrate 112. For example, the filling layer 190 may be configured by a curable adhesive. Specifically, the material which configures the filling layer 190 is coated on the entire surface of the lower substrate 111 and then is cured so that the filling layer 190 may be disposed between the components disposed on the upper substrate 112 and the lower substrate 111.

In the meantime, in FIG. 5, a cross-sectional structure of the display device 100 has been described with respect to the second area A2 of the active area AA in which the plurality of second plate patterns 122P and the plurality of first line patterns 121L which connects adjacent second plate patterns 122P are disposed. However, in the case of the first area A1 of the active area AA, as described with reference to FIGS. 3A to 3C, the cross-sectional area of the display device 100 in the first area A1 is substantially the same as or similar to the cross-sectional structure of the display device 100 in the second area A2 except that the first line pattern 121L is not disposed. Therefore, a redundant description will not be repeated.

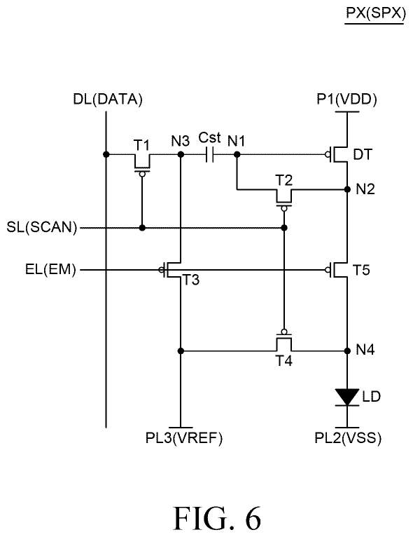

FIG. 6 is a circuit diagram illustrating an example of a pixel included in a display device of FIG. 2.

In the meantime, the pixel circuit illustrated in FIG. 6 indicates an exemplary embodiment of a pixel circuit corresponding to each of the plurality of pixels PX (or the plurality of sub pixels SPX) included in the display device 100 which has been described with reference to FIGS. 1 to 5.

Referring to FIG. 6, at least some of the plurality of transistors included in the plurality of pixels PX (or the plurality of sub pixels SPX) may be an n-type transistor or a p-type transistor. In the case of the p-type transistor, a low level voltage of each driving signal refers to a voltage which turns on a TFT and a high level voltage of each driving signal refers to a voltage which turns off the TFT.

Here, the low level voltage corresponds to a predetermined voltage which is lower than the high level. For example, the low level voltage includes a voltage corresponding to a range of −8 V to −12 V. The high level voltage corresponds to a predetermined voltage which is higher than the low level voltage. For example, the high level voltage includes a voltage corresponding to the range of 12 V to 16 V. According to the exemplary embodiment, the low level voltage is referred to as a first voltage and the high level voltage is referred to as a second voltage. In this case, the first voltage may be lower than the second voltage.

Each of the plurality of pixels PX (or the plurality of sub pixels SPX) includes a driving transistor DT, first to fifth transistors T1 to T5, a storage capacitor Cst, and a light emitting diode LD.

The driving transistor DT controls a driving current applied to the light emitting diode LD in accordance with a source-gate voltage. The driving transistor DT includes a source electrode connected to a high potential power line P1 (or a first power line) which supplies a high potential power voltage VDD (or a first power voltage), a gate electrode connected to the first node N1, and a drain electrode connected to a second node N2.

The first transistor T1 applies a data signal DATA to a third node N3 from the data line DL. The first transistor T1 includes a source electrode connected to the data line DL, a drain electrode connected to the third node N3, and a gate electrode connected to a scan signal line SL to which a scan signal SCAN is applied. The first transistor T1 is turned on or turned off by the scan signal SCAN. Accordingly, the first transistor T1 applies a data signal DATA supplied from the data line DL to the third node N3, in response to a low level of scan signal SCAN which is a turn-on level.

The second transistor T2 forms diode connection of the gate electrode and the drain electrode of the driving transistor DT. The second transistor T2 includes a drain electrode connected to the first node N1, a source electrode connected to the second node N2, and a gate electrode connected to the scan signal line SL to which the scan signal SCAN is applied. The second transistor T2 is turned on or turned off by the scan signal SCAN. Therefore, the second transistor T2 forms a diode connection of the gate electrode and the drain electrode of the driving transistor DT in response to a low level of scan signal SCAN which is a turn-on level.

The third transistor T3 applies a reference voltage VREF to the third node N3. The third transistor T3 includes a source electrode which is connected to the reference voltage line PL3 (or a third power line) which supplies the reference voltage VREF, a drain electrode which is connected to the third node N3, and a gate electrode which is connected to an emission signal line EL to which an emission signal EM is applied. The third transistor T3 is turned on or turned off by the emission signal EM. Accordingly, the third transistor T3 transmits the reference voltage VREF to the third node N3 in response to a low level of emission signal EM which is a turn-on level.

The fourth transistor T4 applies the reference voltage VREF to a fourth node N4, for example, the anode electrode of the light emitting diode LD connected to the fourth node N4. The fourth transistor T4 includes a source electrode connected to the reference voltage line PL3 which supplies the reference voltage VREF, a drain electrode connected to the anode electrode (or the fourth node N4) of the light emitting diode LD, and a gate electrode connected to the scan signal line SL to which the scan signal SCAN is applied. The fourth transistor T4 is turned on or turned off by the scan signal SCAN. Therefore, the fourth transistor T4 applies the reference voltage VREF to the anode electrode of the light emitting diode LD in response to the low level of scan signal SCAN which is a turn on level.

The fifth transistor T5 forms a current path between the driving transistor DT and the light emitting diode LD. The fifth transistor T5 includes a source electrode connected to the second node N2, a drain electrode connected to the fourth node N4, and a gate electrode connected to the emission signal line EL to which the emission signal EM is applied. The fifth transistor T5 is turned on or turned off by the emission signal EM. Therefore, the fifth transistor T5 electrically connects the second node N2 and the fourth node N4 in response to a low level of emission signal EM which is a turn-on level to form a current path between the driving transistor DT and the light emitting diode LD.

The storage capacitor Cst includes a first electrode connected to the first node N1 and a second electrode connected to the third node N3. For example, one electrode of the storage capacitor Cst is connected to the gate electrode of the driving transistor DT and the other electrode of the storage capacitor Cst is connected to the first transistor T1. The storage capacitor Cst stores a predetermined voltage to constantly maintain a voltage of the gate electrode of the driving transistor DT while the light emitting diode LD emits light.

The light emitting diode LD is connected between the fifth transistor T5 and a low potential power line PL2 (or the second power line) which supplies the low potential power voltage VSS (or the second power voltage). For example, one electrode (the anode electrode) of the light emitting diode LD is connected to the fourth node N4 and the other electrode (the cathode electrode) is connected to the low potential power line PL2. The light emitting diode LD emits light by a driving current supplied from the driving transistor DT.

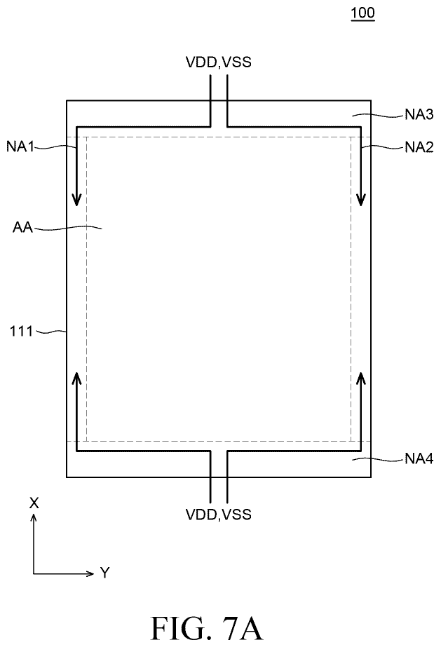

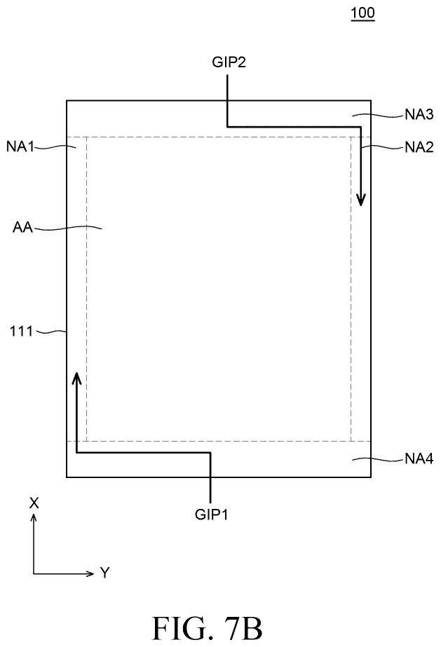

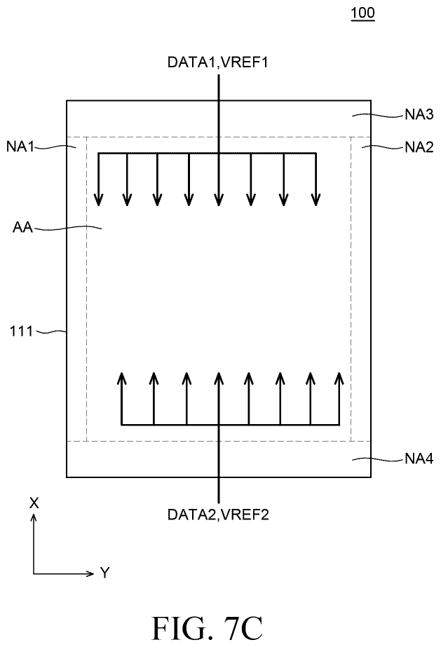

FIGS. 7A to 7C are views for explaining an example of a driving method of a display device of FIG. 2.

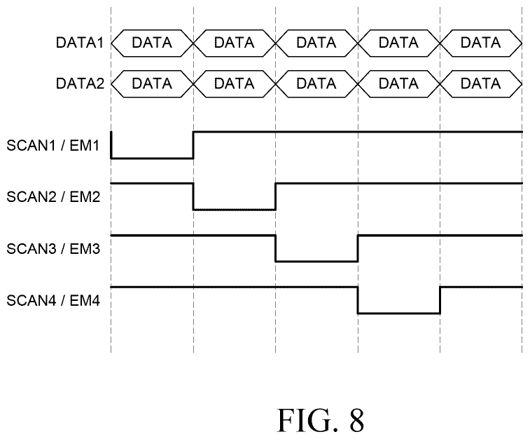

FIG. 8 is a waveform chart for explaining an example of a driving method of a display device of FIG. 2.

In the meantime, for the convenience of description, in FIGS. 7A to 7C, only the lower substrate 111 of the display device 100 and a path through which various signals and voltages are supplied are illustrated.

First, referring to FIG. 7A together with FIGS. 1 and 2, a pixel driving voltage, for example, the high potential power voltage VDD and the low potential power voltage VSS are supplied to the plurality of pixels PX (or the plurality of sub pixels SPX) by a power supply PS disposed in the first non-active area NA1 and the second non-active area NA2, which are the non-active areas NA in both sides of the active area AA.

For example, the high potential power voltage VDD and the low potential power voltage VSS output from the first printed circuit board PCB1 are supplied to a first power supply PS1 disposed on the plurality of third plate patterns 123P of the first non-active area NA1 and a second power supply PS2 disposed on the plurality of third plate patterns 123P of the second non-active area NA2 through the first flexible film 130. Each of the first power supply PS1 and the second power supply PS2 supplies the high potential power voltage VDD and the low potential power voltage VSS to the plurality of pixels PX (or the plurality of sub pixels SPX).

Further, the high potential power voltage VDD and the low potential power voltage VSS output from the second printed circuit board PCB2 are supplied to a first power supply PS1 disposed on the plurality of third plate patterns 123P of the first non-active area NA1 and a second power supply PS2 disposed on the plurality of third plate patterns 123P of the second non-active area NA2 through the second flexible film 230. Each of the first power supply PS1 and the second power supply PS2 supplies the high potential power voltage VDD and the low potential power voltage VSS to the plurality of pixels PX (or the plurality of sub pixels SPX).

As described above, the high potential power voltage VDD and the low potential power voltage VSS are supplied in the non-active areas NA disposed on both sides of the active area AA, that is, the first non-active area NA1 and the second non-active area NA2 so that the degradation of the image quality due to the voltage drop (IR drop) may be suppressed.

Next, referring to FIG. 7B together with FIGS. 1 and 2, gate control signals GIP1 and GIP2 for generating a gate signal of the gate driver GD are supplied to the gate drivers GD disposed in the first non-active area NA1 and the second non-active area NA2 which are non-active areas NA on both sides of the active area AA.

For example, the first gate control signal GIP1 output from the second printed circuit board PCB2 is supplied to odd-numbered stages disposed on the plurality of third plate patterns 123P of the first non-active area NA1, among the plurality of stages of the gate driver GD through the second flexible film 230. Accordingly, the odd-numbered stages of the gate driver GD sequentially supply gate signals to the pixels PX disposed in odd-numbered pixel rows R1, R3, R5, . . . , R13, among the plurality of pixels PX, based on the first gate control signal GIP1.

Further, the second gate control signal GIP2 output from the first printed circuit board PCB1 is supplied to even-numbered stages disposed on the plurality of third plate patterns 123P of the second non-active area NA2, among the plurality of stages of the gate driver GD through the first flexible film 130. Accordingly, the even-numbered stages of the gate driver GD sequentially supply gate signals to the pixels PX disposed in even-numbered pixel rows R2, R4, R6, . . . , R14, among the plurality of pixels PX, based on the second gate control signal GIP2.

Accordingly, further referring to FIG. 8, the gate signal, for example, the scan signals SCAN1 to SCAN4 and the emission signals EM1 to EM4 are sequentially supplied to the plurality of pixels (or the plurality of sub pixels SPX) in the unit of pixel rows, by the odd-numbered stages of the gate driver GD disposed on the plurality of third plate patterns 123P of the first non-active area NA1 and the even-numbered stages of the gate driver GD disposed on the plurality of third plate patterns 123P of the second non-active area NA2.

Further, referring to FIG. 7C together with FIGS. 1 and 2, data signals DATA1 and DATA2 supplied to the plurality of pixels PX (or the plurality of sub pixels SPX) are supplied from the third non-active area NA3 and the fourth non-active area NA4 which are non-active areas NA on the top and the bottom of the active area AA to the active area AA.

For example, a first data signal DATA1 output from the first printed circuit board PCB1 is supplied to the plurality of pixels PX (or the plurality of sub pixels SPX) disposed in the odd-numbered pixel rows through the first driving IC 132 disposed in the first flexible film 130. Further, a second data signal DATA2 output from the second printed circuit board PCB2 is supplied to the plurality of pixels PX (or the plurality of sub pixels SPX) disposed in the even-numbered pixel rows through the second driving IC 232 disposed in the second flexible film 230.

Accordingly, further referring to FIG. 8, the first data signal DATA1 is supplied to the plurality of pixels PX (or the plurality of sub pixels SPX) disposed in the odd-numbered pixel rows so that each pixel PX (or each sub pixel SPX) disposed in the odd-numbered pixel rows emits light with a luminance corresponding to the first data signal DATA1 in response to the corresponding gate signal (for example, a scan signal and an emission signal). Further, the second data signal DATA2 is supplied to the plurality of pixels PX (or the plurality of sub pixels SPX) disposed in the even-numbered pixel rows so that each pixel PX (or each sub pixel SPX) disposed in the even-numbered pixel rows emits light with a luminance corresponding to the second data signal DATA2 in response to the corresponding gate signal (for example, a scan signal and an emission signal).

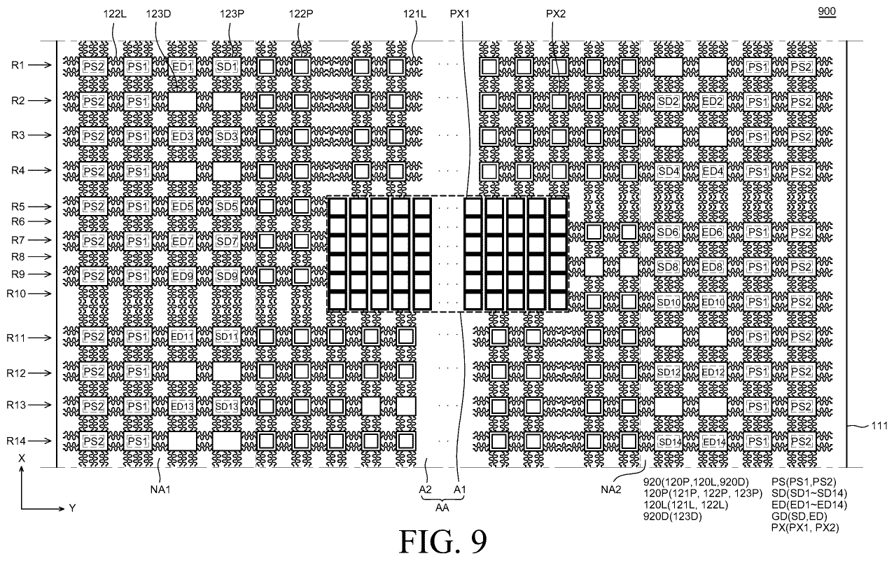

FIG. 9 is a plan view illustrating a display device according to exemplary embodiments of the present disclosure.

In the meantime, a display device 900 of FIG. 9 is a modified embodiment of the display device 100 which has been described with reference to FIG. 2, with regard to a dummy pattern 920D. Accordingly, a repeated description with the content which has been described with reference to FIG. 2 will not be repeated in FIG. 9.

Referring to FIG. 9, a display device 900 according to exemplary embodiments of the present disclosure includes a lower substrate 111, a pattern layer 920, a plurality of pixels PX, a gate driver GD, a data driver, and a power supply PS.

The pattern layer 920 includes a plurality of plate patterns 120P disposed on the lower substrate 111, a plurality of line patterns 120L disposed between the plurality of plate patterns 120P on the lower substrate 111, and a plurality of dummy patterns 920D disposed on the lower substrate 111.

In one exemplary embodiment, as compared with the display device 100 which has been described with reference to FIG. 2, the display device 900 of FIG. 9 does not include the first dummy pattern 121D disposed in the second area A2 of the active area AA and the second dummy pattern 122D disposed in the first non-active area NA1 and the second non-active area NA2. That is, in the case of the display device 900 of FIG. 9, in a part in which a resolution is switched, for example, in the second area A2 corresponding to the boundary part of the first area A1 and the second area A2, the plurality of adjacent second plate patterns 122P is connected through the plurality of first line patterns 121L. Likewise, also in the first non-active area NA1 and the second non-active area NA2 corresponding to the boundary part between the first area A1 and the second area A2, the plurality of adjacent third plate patterns 123P is connected through the plurality of second line patterns 122L.

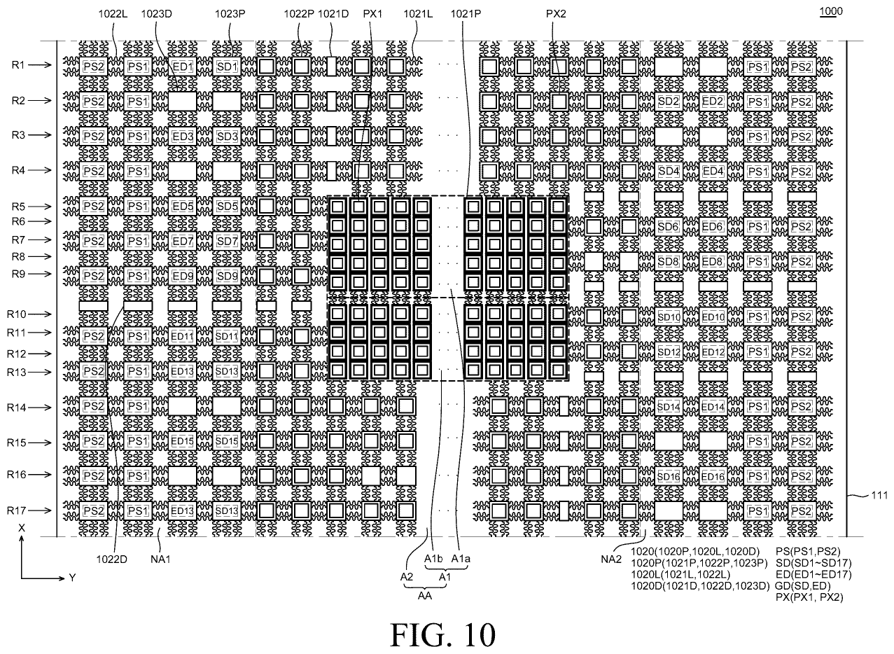

FIG. 10 is a plan view illustrating a display device according to exemplary embodiments of the present disclosure.

In the meantime, a display device 1000 of FIG. 10 is a modified embodiment of the display device 100 which has been described with reference to FIG. 2, with regard to a first area A1 and a pattern layer 1020. Accordingly, a repeated description with the content which has been described with reference to FIG. 2 will not be repeated in FIG. 10.

Referring to FIG. 10, a display device 1000 according to exemplary embodiments of the present disclosure includes a lower substrate 111, a pattern layer 1020, a plurality of pixels PX, a gate driver GD, a data driver, and a power supply PS.

The pattern layer 1020 includes a plurality of plate patterns 1020P disposed on the lower substrate 111, a plurality of line patterns 1020L disposed between the plurality of plate patterns 1020P on the lower substrate 111, and a plurality of dummy patterns 1020D disposed on the lower substrate 111.

In one exemplary embodiment, the first area A1 includes a first sub area A1a and a second sub area A1b excluding the first sub area A1a. For example, the first sub area A1a corresponds to an upper area of the first area A1 and the second sub area A1b corresponds to a lower area of the first area A1 excluding the first sub area A1a.

The plurality of plate patterns 1020P includes a plurality of first plate patterns 1021P and a plurality of second plate patterns 1022P disposed in the active area AA and a plurality of third plate patterns 1023P disposed in the non-active area NA. Further, the plurality of line patterns 1020L includes a plurality of first line patterns 1021L disposed in the active area AA and a plurality of second line patterns 1022L disposed in the non-active area NA. The plurality of dummy patterns 1020D includes a plurality of first dummy patterns 1021D disposed in the active area AA and a plurality of second dummy patterns 1022D and a plurality of third dummy patterns 1023D disposed in the non-active area NA.

The plurality of first plate patterns 1021P is disposed in the first area A1 with the first density and the plurality of second plate patterns 1022P is disposed in the second area A2 with the second density which is lower than the first density. For example, the plurality of first plate patterns 1021P is disposed in the first sub area A1a and the second sub area A1b of the first area A1 with the first density.

In one exemplary embodiment, first plate patterns 1021P which are the most adjacent to the second sub area A1b, among the plurality of first plate patterns 1021P disposed in the first sub area A1b and first plate patterns 1021P which are the most adjacent to the first sub area A1a, among the plurality of first plate patterns 1021P disposed in the second sub area A1b are disposed to be spaced apart from each other. Accordingly, the first plate patterns 1021P which are the most adjacent to the second sub area A1b, among the plurality of first plate patterns 1021P disposed in the first sub area A1b and first plate patterns 1021P which are the most adjacent to the first sub area A1a, among the plurality of first plate patterns 1021P disposed in the second sub area A1b are connected by the plurality of first line patterns 1021L.

Accordingly, in the case of the display device 1000 according to the exemplary embodiments of the present disclosure, only the line pattern extending in the first direction X is disposed in the boundary between the first sub area A1a and the second sub area A1b, for example, the boundary between the first sub area A1a and the second sub area A1b extending along the second direction Y. Therefore, the stretchability along the first direction X may be ensured in the center portion of the display device 1000.

Further, in response to the boundary between the first sub area A1a and the second sub area A1b, for example, the boundary between the first sub area A1a and the second sub area A1b extending along the second direction Y, the plurality of first dummy patterns 1021D having a planar shape is disposed in the second area A2 and the plurality of second dummy patterns 1022D having a planar shape is disposed in the non-active area NA. Accordingly, when the display device 1000 is stretched so as to correspond to the boundary in the center portion, the durability for stretching may be enhanced.

In the meantime, in FIG. 10, the first sub area A1a and the second sub area A1b are divided by an upper area and a lower area of the first area A1 so that the boundary between the first sub area A1a and the second sub area A1b is parallel to the second direction Y, but the exemplary embodiment of the present disclosure is not limited thereto. For example, according to the exemplary embodiment, the first sub area A1a and the second sub area A1b are divided into the left area and the right area of the first area A1 so that the boundary between the first sub area A1a and the second sub area A1b is designed to be parallel to the first direction X.

As described above, in the display device according to the exemplary embodiments of the present disclosure, the first density of the plurality of first plate patterns disposed on the first area corresponding to the center area of the active area is higher than the second density of the plurality of second plate patterns disposed on the second area corresponding to the outside area of the active area. Accordingly, the first pixel density of the pixels disposed on the first area of the active area is higher than the second pixel density of the pixels disposed on the second area of the active area.

Therefore, in the case of the display device according to the exemplary embodiments of the present disclosure, in a first area which is a center area of an active area in which the stretching is not necessary and the user's eyes are focused, a high resolution image may be displayed. In a second area which is an outside area of the active area in which the stretching is necessary and the user's eyes are relatively less focused, the stretchability is ensured by a line pattern. Accordingly, in the case of the display device according to the exemplary embodiments of the present disclosure, in the outside area in which the stretching is necessary, the stretching is possible and in the center area in which the user's eyes are focused, a high resolution image can be displayed.

Further, in the case of the display device according to the exemplary embodiments of the present disclosure, as a part in which a resolution is switched, in a second area corresponding to a boundary part between the first area and the second area of the active area and/or a non-active area, a plurality of dummy patterns having a planar shape is disposed. Accordingly, the stretchability of the display device is ensured and a durability for the stretching is enhanced.

The exemplary embodiments of the present disclosure can also be described as follows:

In some embodiments, a display device may include a substrate 111 having an active area AA and a non-active area NA adjacent to the active area AA. The active area AA may further include a first area A1 and a second area A2 disposed adjacent to the first area A1. A plurality of plate patterns may be disposed on the substrate 111, including first plate patterns located in the first area A1 and second plate patterns located in the second area A2. The first plate patterns in the first area may be in direct contact with one another without gaps, thereby forming a substantially continuous region in A1. In contrast, the second plate patterns in the second area A2 may be spaced apart from each other by gaps. A plurality of line patterns may be disposed only in the second area A2 and may extend across the gaps between adjacent second plate patterns. In this embodiment, the line patterns are absent from the first area A1.

Further, in this embodiment, the first plate patterns in the first area A1 may be formed as a single, continuous plate region covering the entirety of the first area A1. This continuous plate region eliminates gaps within the first area, providing a unitary rigid island beneath the pixels disposed in the first area A1.

In some embodiments, pixels may be disposed on the first plate patterns in the first area A1, and pixels may be disposed on the second plate patterns in the second area A2. The pixels in the first area A1 may be arranged at a first pixel density, while the pixels in the second area A2 may be arranged at a second pixel density that is lower than the first pixel density. The higher pixel density in the first area allows for higher resolution in a central region, while the lower density in the second area provides increased stretchability.

In some embodiments, each line pattern of the plurality of line patterns in the second area A2 may extend across the gaps between adjacent second plate patterns along a non-linear path. The non-linear routing provides additional compliance during stretching of the device. The non-linear path of the line patterns may include either a wavy shape or a zigzag shape. These geometries enhance the extensibility of the line patterns, thereby improving the mechanical flexibility of the second area A2 during stretching of the substrate.

In some embodiments, dummy patterns may be arranged at the boundary between the first area A1 and the second area A2. The dummy patterns may be disposed along virtual extension lines projected outward from edges of the first area A1 into the second area A2 and into the adjacent non-active region NA. The dummy patterns may be formed of the same material and thickness as the plate patterns. The dummy patterns are positioned along the boundary so as to distribute mechanical stress in regions adjacent to the first area A1, thereby enhancing durability and uniform stretchability of the panel.

In some embodiments, as shown in FIG. 10, a display device may include a substrate 111 with an active area AA and a non-active area NA adjacent thereto. The active area AA may include a first area A1 and a second area A2 adjacent to the first area, where the first area A1 is subdivided into a first sub-area A1a and a second sub-area A1b. A plurality of plate patterns may be disposed on the substrate, including first plate patterns in the first sub-area A1a, second plate patterns in the second area A2, and third plate patterns in the second sub-area A1b. The second plate patterns may be spaced apart from each other by gaps, while the first plate patterns and third plate patterns are in direct contact with one another without gaps in their respective sub-areas. A plurality of line patterns may extend across gaps between adjacent second plate patterns.

As further shown in FIG. 10, the plurality of line patterns may also extend along a boundary between the first sub-area A1a and the second sub-area A1b. The presence of the line patterns along this boundary provides enhanced extensibility within the central high-density region.

In the embodiment of FIG. 10, the plurality of line patterns are absent from the interiors of the first sub-area A1a and the second sub-area A1b, and are disposed only along the boundary between them and within the second area A2. This arrangement maintains rigidity within the sub-areas while allowing controlled stretchability at the sub-area boundary.

As shown in FIG. 10, dummy patterns may be disposed in the second area A2 adjacent to the boundary between the first sub-area A1a and the second sub-area A1b. The dummy patterns reinforce the region adjacent to the sub-area boundary to maintain durability when the central portion of the panel is stretched.

As further illustrated in FIG. 10, dummy patterns may be disposed in the non-active area NA aligned with the boundary between the first sub-area A1a and the second sub-area A1b. This arrangement provides mechanical continuity into the non-active region.

Still referring to FIG. 10, the dummy patterns disposed in the non-active area NA may have substantially the same width as the dummy patterns disposed in the second area A2. This dimensional consistency ensures uniform mechanical response across the boundary and adjacent regions.

Further embodiments of the present disclosure can also be described as follows:

According to an aspect of the present disclosure, a display device includes a lower substrate including an active area having a first area and a second area surrounding the first area, and a non-active area excluding the active area; a plurality of plate patterns on the lower substrate; a plurality of line patterns between the plurality of plate patterns on the lower substrate; and a plurality of pixels on a plurality of plate patterns in the active area, among the plurality of plate patterns. The plurality of pixels is disposed in the first area and the second area with different pixel densities.

The plurality of plate patterns may include a plurality of first plate patterns in the first area with a first density; and a plurality of second plate patterns in the second area with a second density which is lower than the first density.

Each of the plurality of first plate patterns may be disposed so as to be in direct contact with an adjacent first plate pattern.

The line pattern may be disposed between the plurality of second plate patterns in the second area and is not disposed in the first area.

The plurality of pixels may include a plurality of first pixels on each of the plurality of first plate patterns; and a plurality of second pixels on each of the plurality of second plate patterns. The plurality of first pixels may be disposed in the first area with a first pixel density and the plurality of second pixels may be disposed in the second area with a second pixel density which is lower than the first pixel density.

The plurality of plate patterns may include one first plate pattern in the first area; and a plurality of second plate patterns in the second area.

The plurality of pixels may include a plurality of first pixels on the first plate pattern; and a plurality of second pixels on each of the plurality of second plate patterns. The plurality of first pixels may be disposed in the first area with a first pixel density and the plurality of second pixels may be disposed in the second area with a second pixel density which is lower than the first pixel density.

The non-active area may include a first non-active area on one side of the active area; and a second non-active area on the other side of the active area. The plurality of plate patterns may include a plurality of third plate patterns on the first non-active area and the second non-active area.

The display device may further include a gate driver including a plurality of stages which is disposed on each of the plurality of third plate patterns. Odd-numbered stages among the plurality of stages of the gate driver may be disposed on a plurality of third plate patterns disposed on the first non-active area, among the plurality of third plate patterns, and even-numbered stages among the plurality of stages of the gate driver may be disposed on a plurality of third plate patterns disposed on the second non-active area, among the plurality of third plate patterns.

The odd-numbered stages may be disposed on the plurality of third plate patterns disposed so as to correspond to odd-numbered pixel rows of the plurality of pixels, among the plurality of third plate patterns on the first non-active area, and the even-numbered stages may be disposed on the plurality of third plate patterns disposed so as to correspond to even-numbered pixel rows of the plurality of pixels, among the plurality of third plate patterns on the second non-active area.

The first area may include a first side parallel to a first direction, a second side which is parallel to the first direction and is opposite to the first side, a third side parallel to a second direction different from the first direction, and a fourth side which is parallel to the second direction and is opposite to the third side. The display device may further include a plurality of first dummy patterns which is disposed on the second area and is (e.g., sequentially) spaced apart from each other along a direction parallel to any one side among the first to fourth sides of the first area, on a virtual extending line for the any one side.

The display device may further include a plurality of second dummy patterns which is disposed on the non-active area and is (e.g., sequentially) spaced apart from each other along a direction parallel to the any one side on the virtual extending line.

The first area may include a first sub area and a second sub area excluding the first sub area, and a first plate pattern which is the most adjacent to the second sub area, among the plurality of first plate patterns in the first sub area and a first plate pattern which is the most adjacent to the first sub area, among the plurality of first plate patterns in the second sub area may be spaced apart from each other.

According to another aspect of the present disclosure, a display device includes a lower substrate including an active area having a first area and a second area surrounding the first area, and a non-active area excluding the active area; a plurality of plate patterns on the lower substrate; and a plurality of line patterns between the plurality of plate patterns on the lower substrate. The plurality of plate patterns overlaps at least a part of the second area and does not overlap the first area.

The display device may further include a plurality of first pixels directly disposed on the lower substrate in the first area; and a plurality of second pixels on each of the plurality of plate patterns. The plurality of first pixels may be disposed in the first area with a first pixel density and the plurality of second pixels may be disposed in the second area with a second pixel density which is lower than the first pixel density.

According to yet another aspect of the present disclosure, a display device includes a lower substrate including an active area having a first area and a second area surrounding the first area, and a non-active area excluding the active area; a plurality of plate patterns on the lower substrate; a plurality of line patterns between the plurality of plate patterns on the lower substrate; and a plurality of pixels on a plurality of plate patterns in the active area, among the plurality of plate patterns. A plurality of plate patterns in the first area, among the plurality of plate patterns, is disposed to be in direct contact with an adjacent plate pattern and a plurality of plate patterns in the second area, among the plurality of plate patterns, is disposed to be spaced apart from each other.

The plurality of plate patterns may include a plurality of first plate patterns in the first area with a first density; and a plurality of second plate patterns in the second area with a second density which is lower than the first density. The line pattern may be disposed between the plurality of second plate patterns in the second area and may be not disposed in the first area.

The first area may include a first side parallel to a first direction, a second side which is parallel to the first direction and is opposite to the first side, a third side parallel to a second direction different from the first direction, and a fourth side which is parallel to the second direction and is opposite to the third side. The display device may further include a plurality of first dummy patterns which is disposed on the second area and is (e.g., sequentially) spaced apart from each other along a direction parallel to any one side among the first to fourth sides of the first area, on a virtual extending line for the any one side.

The display device may further include a plurality of second dummy patterns on the non-active area and (e.g., sequentially) spaced apart from each other along a direction parallel to the any one side on the virtual extending line.

The first area may include a first sub area and a second sub area excluding the first sub area and a first plate pattern which is the most adjacent to the second sub area, among the plurality of first plate patterns in the first sub area and a first plate pattern which is the most adjacent to the first sub area, among the plurality of first plate patterns in the second sub area may be spaced apart from each other.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including an active area having a first area and a second area adjacent to the first area, and a non-active area excluding the active area;
a plurality of plate patterns on the substrate;
a plurality of line patterns between adjacent plate patterns of the plurality of plate patterns; and
a plurality of pixels on a plurality of plate patterns in the active area, among the plurality of plate patterns,
wherein the plurality of pixels is disposed in the first area and the second area with different pixel densities.

2. The display device according to claim 1, wherein the plurality of plate patterns in the active area includes:
a plurality of first plate patterns in the first area with a first density; and
a plurality of second plate patterns in the second area with a second density which is lower than the first density.

3. The display device according to claim 2, wherein each of the plurality of first plate patterns is disposed so as to be in direct contact with an adjacent first plate pattern.

4. The display device according to claim 2, wherein the plurality of line patterns is partially disposed between the plurality of second plate patterns in the second area and none of the plurality of line patterns is disposed in the first area.

5. The display device according to claim 2, wherein the plurality of pixels includes:
a plurality of first pixels on each of the plurality of first plate patterns; and
a plurality of second pixels on each of the plurality of second plate patterns,
wherein the plurality of first pixels is disposed in the first area with a first pixel density and the plurality of second pixels is disposed in the second area with a second pixel density which is lower than the first pixel density.

6. The display device according to claim 1, wherein the plurality of plate patterns includes:
a single first plate pattern in the first area; and
a plurality of second plate patterns in the second area.

7. The display device according to claim 6, wherein the plurality of pixels includes:
a plurality of first pixels on the single first plate pattern; and
a plurality of second pixels on each of the plurality of second plate patterns,
wherein the plurality of first pixels is disposed in the first area with a first pixel density and the plurality of second pixels is disposed in the second area with a second pixel density which is lower than the first pixel density.

8. The display device according to claim 1, wherein the non-active area includes:
a first non-active area on one side of the active area; and
a second non-active area on the other side of the active area, and
wherein the plurality of plate patterns includes a plurality of third plate patterns on the first non-active area and the second non-active area.

9. The display device according to claim 8, further comprising:
a gate driver including a plurality of stages which is on the plurality of third plate patterns,
wherein odd-numbered stages among the plurality of stages of the gate driver are on the third plate patterns on the first non-active area, among the plurality of third plate patterns, and
wherein even-numbered stages among the plurality of stages of the gate driver are on the third plate patterns on the second non-active area, among the plurality of third plate patterns.

10. The display device according to claim 9, wherein the odd-numbered stages are on the third plate patterns disposed so as to correspond to odd-numbered pixel rows of the plurality of pixels, among the plurality of third plate patterns on the first non-active area, and
wherein the even-numbered stages are on the third plate patterns disposed so as to correspond to even-numbered pixel rows of the plurality of pixels, among the plurality of third plate patterns on the second non-active area.

11. The display device according to claim 1, wherein the first area includes a first side parallel to a first direction, a second side which is parallel to the first direction and is opposite to the first side, a third side parallel to a second direction different from the first direction, and a fourth side which is parallel to the second direction and is opposite to the third side, and
wherein the display device further comprises:
a plurality of first dummy patterns which is on the second area and is spaced apart from each other along a direction parallel to any one side among the first to fourth sides of the first area, on a virtual extending line for the any one side.

12. The display device according to claim 11, further comprising:
a plurality of second dummy patterns which is on the non-active area and is spaced apart from each other along a direction parallel to the any one side on the virtual extending line.

13. The display device according to claim 2, wherein the first area includes a first sub area and a second sub area excluding the first sub area, and
wherein a first plate pattern which is the most adjacent to the second sub area, among the plurality of first plate patterns in the first sub area and a first plate pattern which is the most adjacent to the first sub area, among the plurality of first plate patterns in the second sub area are spaced apart from each other.

14. A display device, comprising:
a substrate including an active area having a first area and a second area adjacent to the first area, and a non-active area excluding the active area;
a plurality of plate patterns on the substrate; and
a plurality of line patterns between adjacent plate patterns of the plurality of plate patterns,
wherein the plurality of plate patterns overlaps at least a part of the second area and does not overlap the first area.

15. The display device according to claim 14, further comprising:
a plurality of first pixels directly on the substrate in the first area; and
a plurality of second pixels on each of the plurality of plate patterns,
wherein the plurality of first pixels is disposed in the first area with a first pixel density and the plurality of second pixels is disposed in the second area with a second pixel density which is lower than the first pixel density.

16. The display device according to claim 14, wherein the plurality of line patterns being absent from the first area.

17. A display device, comprising:
a substrate including an active area having a first area and a second area adjacent to the first area, and a non-active area excluding the active area;
a plurality of plate patterns on the substrate;
a plurality of line patterns between adjacent plate patterns of the plurality of plate patterns; and
a plurality of pixels on a plurality of plate patterns in the active area, among the plurality of plate patterns,
wherein a plurality of plate patterns in the first area, among the plurality of plate patterns in the active area, is disposed to be in direct contact with an adjacent plate pattern and a plurality of plate patterns in the second area, among the plurality of plate patterns in the active area, is disposed to be spaced apart from each other.

18. The display device according to claim 17, wherein the plurality of plate patterns in the active area includes:
a plurality of first plate patterns in the first area with a first density; and
a plurality of second plate patterns in the second area with a second density which is lower than the first density, and
wherein the plurality of line patterns is partially disposed between the plurality of second plate patterns in the second area and none of the plurality of line patterns is disposed in the first area.

19. The display device according to claim 18, wherein the first area includes a first sub area and a second sub area excluding the first sub area, and
wherein a first plate pattern which is the most adjacent to the second sub area, among the plurality of first plate patterns in the first sub area and a first plate pattern which is the most adjacent to the first sub area, among the plurality of first plate patterns in the second sub area are spaced apart from each other.

20. The display device of claim 2, wherein each line pattern of the plurality of line patterns extends along a non-linear path between adjacent ones of the second plate patterns.

21. The display device of claim 20, wherein the non-linear path includes a wavy shape or a zigzag shape.

22. The display device of claim 17, further comprising:
dummy patterns arranged at a boundary between the first area and the second area,
wherein the dummy patterns are disposed along virtual extension lines projected from edges of the first area, and
wherein the dummy patterns are positioned along the boundary to distribute mechanical stress in regions adjacent to the first area.

23. A display device, comprising:
a substrate including an active area and a non-active area adjacent to the active area, the active area having a first area and a second area adjacent to the first area, the first area having a first sub-area and a second sub-area adjacent to the first sub-area;
a plurality of plate patterns on the substrate including first plate patterns in the first sub-area, second plate patterns in the second area, and third plate patterns in the second sub-area, the second plate patterns being spaced apart from each other by gaps; and
a plurality of line patterns extending across gaps between adjacent ones of the second plate patterns,
wherein the first plate patterns are in direct contact with one another without gaps, and
wherein the third plate patterns are in direct contact with one another without gaps.

24. The display device of claim 23, wherein the plurality of line patterns extends along a boundary between the first sub-area and the second sub-area.

25. The display device of claim 24, wherein the plurality of line patterns is absent from the first sub-area and the second sub-area.

26. The display device of claim 24, wherein pixels of the first sub-area and the second sub-area are disposed at a higher pixel density than pixels of the second area.

27. The display device of claim 23, further comprising dummy patterns,
wherein the dummy patterns are disposed in the second area adjacent to the boundary between the first and second sub-areas.

28. The display device of claim 23, further comprising dummy patterns,
wherein the dummy patterns are disposed in a non-active area aligned with the boundary between the first and second sub-areas.

29. The display device of claim 23, further comprising dummy patterns,
wherein the dummy patterns disposed in the non-active area have substantially the same width as the dummy patterns in the second area.
